(19) United States
(12) Patent Application Publication
(10) Pub. No.: US 2025/0294896 A1
(43) Pub. Date: Sep. 18, 2025

(54) INTEGRATED CIRCUITS DEVICES, SYSTEMS AND METHODS

(71) Applicants: Darryl G. Walker, San Jose, CA (US); Bradley T. Sako, Livermore, CA (US)

(72) Inventors: Darryl G. Walker, San Jose, CA (US); Bradley T. Sako, Livermore, CA (US)

(21) Appl. No.: 19/080,831

(22) Filed: Mar. 15, 2025

Related U.S. Application Data
(60) Provisional application No. 63/566,873, filed on Mar. 18, 2024.

(51) Int. Cl. H10D 89/60; H01L 23/522; H01L 23/528; H10D 84/01; H10D 84/83

(52) U.S. Cl. CPC H10D 89/811; H01L 23/5226; H01L 23/5283; H01L 23/5286; H10D 84/0128; H10D 84/0149; H10D 84/83

(57) ABSTRACT

A method can include receiving first, second and third power supply voltages at first, second and third terminals, respectively, located at a first side of an IC device. First, second and third rows of insulated gate field effect transistors (IGFETs) can be formed at a second side. A first power supply can be coupled from the first terminal to an IGFET in the first row via a first conductive via and first conductive line. A second power supply can be coupled from the second terminal to an IGFET in the second row via a second conductive via and second conductive line. A third power supply can be coupled from the third terminal to an IGFET in the third row via a third conductive via and third conductive line. Corresponding devices and systems are also disclosed.

### CROSS-REFERENCE TO RELATED APPLICATIONS

The present application claims the priority and benefit of U.S. Patent Application Number No. 63/566,873 filed on Mar. 18, 2024, the contents of which are incorporated by reference herein in their entirety.

### TECHNICAL FIELD

The present disclosure relates generally to an integrated circuit (IC) device, and more particularly to improving supply potential integrity and routing efficiency, electrostatic discharge (ESD) protection, and circuit compactness and functionality for such an IC device.

### BACKGROUND

As integrated circuitry shrinks, power supply potentials may include fluctuations due to high resistivity interconnect. ESD protection may also consume prohibitively large amounts of integrated circuit (IC) real estate. Power supply and signal routing may also consume an excessive amount of IC real estate as compared to other circuitry such as active devices (transistors and the like).

In light of the above, it would be desirable to provide a method of improving supply potential integrity and routing efficiency, electrostatic discharge (ESD) protection, and circuit compactness and functionality.

### SUMMARY

A method can include receiving first, second and third power supply voltages at first, second and third terminals, respectively, located at a first side of an IC device. First, second and third rows of insulated gate field effect transistors (IGFETs) can be formed at a second side. A first power supply can be coupled from the first terminal to an IGFET in the first row via a first conductive via and first conductive line. A second power supply can be coupled from the second terminal to an IGFET in the second row via a second conductive via and second conductive line. A third power supply can be coupled from the third terminal to an IGFET in the third row via a third conductive via and third conductive line. Corresponding devices and systems are also disclosed.

### BRIEF DESCRIPTION OF DRAWINGS

FIG. 1 is a side cross sectional view of an integrated circuit (IC) device according to an embodiment.

FIG. 2 is a side cross sectional view of an IC device according to another embodiment.

FIG. 3 is a side cross sectional view of an IC device according to another embodiment.

FIGS. 4A, 4B, 4C, 4D, 4E, 4F and 4G are top plan views showing fabrication steps of an IC device according to an embodiment.

FIG. 5 is a top plan view of an IC device according to an embodiment.

FIG. 6 is a top view of an IC device according to a further embodiment.

FIGS. 7A, 7B, 7C and 7D are top views showing fabrication steps of an IC device according to an embodiment.

FIGS. 8A, 8B, 8C and 8D are top cross sectional views of through vias that can be included in embodiments.

FIGS. 9A, 9B and 9C are side cross sectional views of connections between buried conductive lines and through vias that can be included in embodiments.

FIGS. 10A, 101B, 10C and 10D are top views showing connections between buried conductive lines and through vias that can be included in embodiments.

FIG. 11 is a top view showing connections between buried conductive lines and through vias that can be included in embodiments.

FIGS. 12A and 12B are top and side cross sectional views of connections between buried conductive lines and through vias that can be included in embodiments.

FIGS. 13A and 13B are top and side cross sectional views of connections between buried conductive lines and through vias that can be included in embodiments.

FIGS. 14A and 14B are top and side cross sectional views of connections between buried conductive lines and through vias that can be included in embodiments.

FIGS. 15A and 15B are top and side cross sectional views of connections between buried conductive lines and through vias that can be included in embodiments.

FIG. 16 is a top plan view showing input or output signal paths that can be included in embodiments.

FIGS. 17A, 17B and 17C are top and side cross sectional views of dummy structures that can be included in embodiments.

FIGS. 18A, 18B and 18C are top and side cross sectional views IC devices according to additional embodiments.

FIGS. 19A, 19B and 19C are side cross sectional views showing connections between an insulated gate field effect transistor (IGFET) source or drains (S/D) and through vias according to an embodiment.

FIGS. 20A, 20B and 20C are side cross sectional views showing connections between an IGFET S/D and through vias according to another embodiment.

FIGS. 21A, 21B and 21C are side cross sectional views showing connections between an IGFET S/D and through vias according to a further embodiment.

FIGS. 22A, 22B and 22C are side cross sectional views showing connections between an IGFET S/D and through vias according to a further embodiment.

FIG. 23 is a side cross sectional view of an IC device according to another embodiment.

FIG. 24 is a side cross sectional view of an IC device showing connections to a back side circuit according to an embodiment.

FIG. 25 is a side cross sectional view of an IC device showing connections to a back side circuit according to another embodiment.

FIG. 26 is a side cross sectional view of an IC device showing connections to a back side circuit according to a further embodiment.

FIG. 27 is a side cross sectional view of an IC device showing connections to a back side circuit according to another embodiment.

FIG. 28 is a side cross sectional view of an IC device showing connections to a back side electrostatic discharge protection (ESD) circuit according to an embodiment.

FIG. 29 is a side cross sectional view of an IC device showing connections to a back side ESD circuit according to another embodiment.

FIG. 30A is a schematic diagram of an ESD circuit according to an embodiment.

FIG. 30B is a schematic diagram of an ESD circuit according to another embodiment.

FIG. 30C is a schematic diagram of an ESD circuit according to a further embodiment.

FIG. 30D is a schematic diagram of an ESD circuit according to another embodiment.

FIG. 30E is a schematic diagram of an ESD circuit according to another embodiment.

FIG. 30F is a schematic diagram of an ESD circuit according to another embodiment.

FIG. 30G is a schematic diagram of an ESD circuit according to another embodiment.

FIG. 31A is a side cross sectional view of an IC device showing a back side circuit element according to an embodiment. FIG. 31B is a side cross sectional view of an IC device showing a back side circuit element according to another embodiment. FIG. 31C is a side cross sectional view of an IC device showing a back side circuit element according to a further embodiment.

FIG. 32 is a block schematic diagram showing first and second substrate side locations of IC device circuits according to an embodiment.

FIG. 33 is a block schematic diagram showing first and second substrate side locations of IC device circuits according to another embodiment.

FIG. 34 is a block schematic diagram showing first and second substrate side locations of IC device circuits according to a further embodiment.

FIG. 35A is a back side view of an IC device with a back side ESD circuit according to an embodiment. FIG. 35B is a back side view of an IC device with a back side ESD circuit according to another embodiment. FIG. 35C is a back side view of an IC device with a back side ESD circuit according to a further embodiment.

FIG. 36A is a side cross sectional view of an IC device showing a back side circuit element according to another embodiment. FIG. 36B is a side cross sectional view of an IC device showing a back side circuit element according to another embodiment. FIG. 36C is a back side view of an IC device showing a back side circuit element according to a further embodiment.

FIG. 37 is a back side view of an IC device showing a back side circuit element according to another embodiment.

FIG. 38 is a back side view of an IC device showing back routing of power supply voltages and signals according to an embodiment.

FIG. 39A is a side cross sectional view of an IC device connection according to an embodiment. FIG. 39B is a side cross sectional view of an IC device connection according to another embodiment. FIG. 39C is a side cross sectional view of an IC device connection according to a further embodiment.

FIG. 40A is a side cross sectional view showing an IC device in a fabrication process according to an embodiment. FIG. 40B is a side cross sectional view showing an IC device in a fabrication process according to an embodiment. FIG. 40C is a side cross sectional view showing an IC device in a fabrication process according to an embodiment. FIG. 40D is a side cross sectional view showing an IC device in a fabrication process according to an embodiment. FIG. 40E is a side cross sectional view showing an IC device in a fabrication process according to an embodiment.

FIG. 41A is a side cross sectional view showing an IC device in a fabrication process according to an embodiment. FIG. 41B is a side cross sectional view showing an IC device in a fabrication process according to an embodiment. FIG. 41C is a side cross sectional view showing an IC device in a fabrication process according to an embodiment.

FIG. 42 is a side cross sectional view of a system according to an embodiment.

FIG. 43 is a side cross sectional view of a system according to another embodiment.

FIG. 44 is a side cross sectional view of a system according to a further embodiment.

FIG. 45 is a side cross sectional view of a system according to another embodiment.

FIG. 46 is a side cross sectional view of a system according to another embodiment.

FIG. 47 is a side cross sectional view of a system according to another embodiment.

FIG. 48 is a side cross sectional view of a system according to another embodiment.

FIGS. 49A and 49B are top plan views showing an IC device according to additional embodiment.

### DETAILED DESCRIPTION

According to embodiments, an integrated circuit device can include a first side (e.g., back side) and a second side (e.g., front side). Rows of insulated gate field effect transistors (IGFETs) can be formed at the second side, and can include first rows formed of IGFETs of a first conductivity type and second rows of IGFETs of a second conductivity type. IGFETs in first and second rows can be connected to form logic circuits. First and second conductive lines can be buried in the second side below the rows of IGFETs. Within each circuit, a source/drain (S/D) of one or more IGFETs from the first row can be electrically connected to a first conductive line. A first conductive line can be electrically connected to a first terminal located at the first side by a first conductive via. A second conductive line can be electrically connected to a second terminal located at the first side by a second conductive via. First and second conductive vias can extend between the first and second sides.

In some embodiments, a first power supply voltage (e.g., VDD or VSS) can be provided to a first terminal. A first power supply voltage can be provided to the circuits through a first via and a first conductive line.

In some embodiments, a second power supply voltage (e.g., VSS or VDD) can be provided to a second terminal. A second power supply voltage can be provided to the circuits through a second via and a second conductive line.

In some embodiments, first and second rows can extend in a first direction adjacent to one another at the second side.

In some embodiments, a first row can be formed over a second row with respect to the second side, forming stacked pairs of IGFETs of different conductivity types.

In some embodiments, an electrostatic discharge (ESD) protection circuit can be formed at the first side, electrically connected to a first terminal.

In some embodiments, an IC device can include multiple first conductive lines that each extend in a first direction and are parallel to one another. First conductive vias can be electrically connected to each first conductive line and be offset from one another in the first direction.

In some embodiments, an IC device can also include an input or output (I/O) conductive structure buried in, and proximate to the second side below the first and second rows of IGFETs. An I/O conductive structure can be electrically connected to logic circuits. An I/O conductive structure can also be electrically connected to an I/O conductive via that extends from the second side to an I/O terminal at the first side. A logic circuit can receive and/or transmit an electrical signal by way of the signal path formed by the I/O conductive structure, I/O conductive via and I/O terminal.

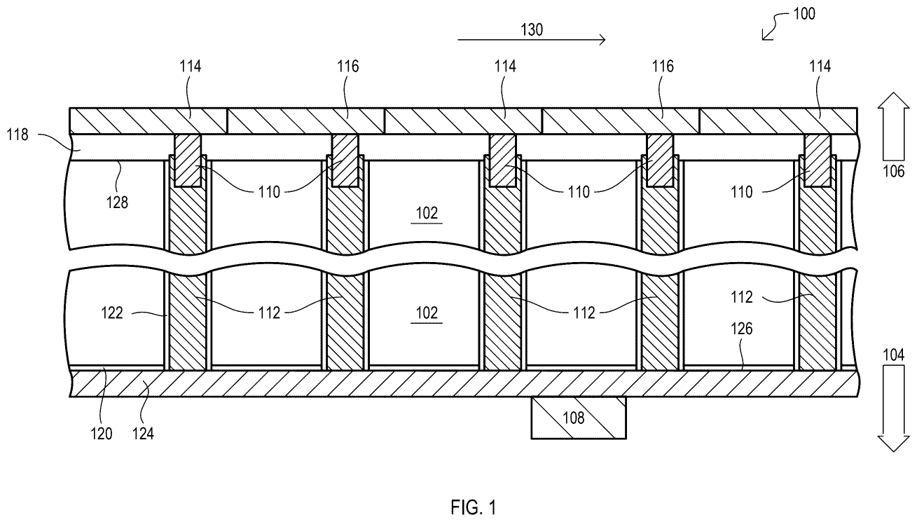

Referring to FIG. 1, an IC device 100 according to an embodiment is shown in a side cross sectional view. IC device 100 can include a substrate 102, a first side 104 and a second side 106. A substrate 102 can be formed of a single layer (e.g., a monocrystalline) or multiple layers. A terminal 108 can be formed at the first side 104. Buried conductive lines 110 can be formed at the second side 106. In some embodiments, buried conductive lines 110 can be parallel to one another and extend in a first direction (i.e., into the cross sectional plane of FIG. 1) and can be adjacent to one another in second direction 130. Buried conductive lines 110 can be considered “buried” as they can be formed, all or in part, into a second surface 128 of substrate 102.

Through vias 112 can extend substantially through substrate 102 between first and second sides (104, 106). First IGFET portions 114 and second IGFET portions 116 can be formed at the second side 106 over buried conductive lines 110. IGFET portions (114, 116) can each include one or more IGFETs. In some embodiments, IGFET portions (114, 116) can each be part of a row of IGFETs of different conductivity type (with such rows extending into the plane shown by the cross section). In some embodiments, IGFET portions (114, 116) can each include two or more IGFETs stacked on top of one another. Such stacked IGFETs can be part of a row of IGFETs of different conductivity type, with such rows extending in a first direction (into the plane shown by the cross section of FIG. 1). In some embodiments, IGFET portions (114, 116) can be adjacent to one another in the second direction 130.

A through via 112 can provide a conductive path between a terminal 108 and one or more buried conductive lines 110. In some embodiments, a through via 112 can be a through silicon via (TSV), however, this should not be construed as limiting. According to embodiments, through via 112 can provide a conductive path between terminal 108 and buried conductive line 110. Such a conductive path can carry any suitable signal/voltage, including but not limited to a power supply voltage, input signal and/or output signal.

In the embodiment shown, an IC device 100 can include a front side insulator 118 and a back side insulator 120. A front side insulator 118 can be formed on a first surface 128 of substrate 102. Back side insulator 120 can be formed on a back side of substrate 102. Front and back side insulators (118, 120) can be formed of a single layer of an insulating material, or multiple such layers. IGFET portions (114, 116) can be formed over and/or on front side insulator 118. Buried conductive lines 110 can have a conductive connection to IGFET portions (114, 116) through front side insulator 118. Such a connection can be by a buried conductive line 110 contacting an IGFET portion (114, 116), by a contact or surface via structure (not shown) that extends upward from a buried conductive line 110, and/or combinations thereof. All or portions of through vias 112 can be insulated from a substrate 102 by a via insulator (one shown as 122).

In the embodiment shown, a back side routing 124 can be formed over the back side insulator 120. A back side routing 124 can provide a conductive path between a terminal 108 and one or more through vias 112. In this way, a through via 112 can provide a conductive path between a terminal 108 and one or more buried conductive lines 110. A back side routing 124 can be formed from any suitable conductive material, and can formed from one layer or multiple layers. In some embodiments, a back sider routing 124 can be patterned using and suitable method, including but not limited to deposition and etch and/or deposit and planarize (e.g., damascene-like methods).

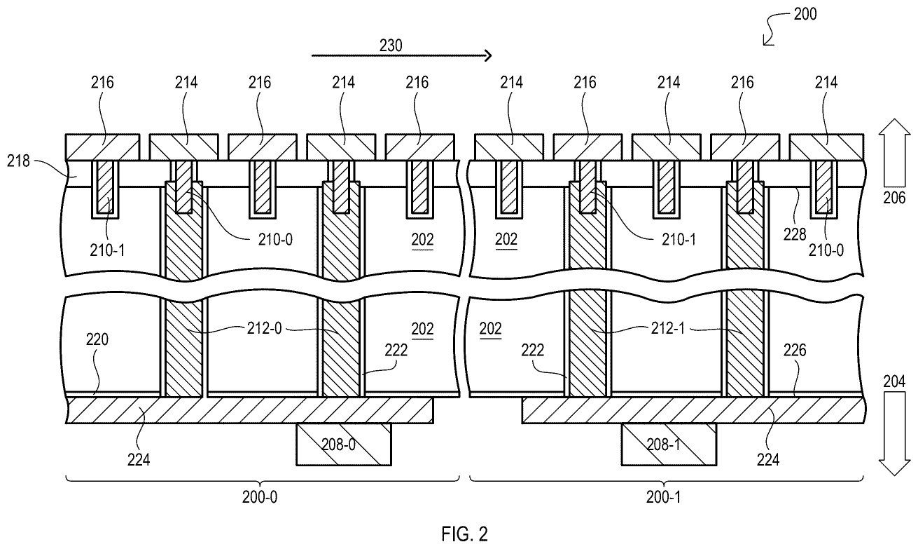

Referring to FIG. 2, an IC device 200 according to another embodiment is shown in a side cross sectional view. In some embodiments, IC device 200 can be one implementation of that shown in FIG. 1. IC device 200 can include items like those of FIG. 1, and such like items are referred to by the same reference character but with the leading digit being a “2” instead of a “1”.

IC device 200 can include first rows of IGFETs 214 and second rows of IGFETs 216. Such first and second rows (214, 216) can extend in a first direction (into the cross sectional plane) and adjacent to one another in a second direction 230. While FIG. 2 shows alternating first and second rows (214, 216) in second direction 230, alternate embodiments can include rows of the same type adjacent to one another on the second direction 230. First rows of IGFETs 214 can include IGFETs of a first conductivity type (e.g., n-type) and second rows of IGFETs 216 can include IGFETs of a second conductivity type (e.g., p-type). In FIG. 2, conductive lines can include first conductive lines 210-0 and second conductive lines 210-1 and through vias can include first through vias 212-0 and second through vias 212-1.

FIG. 2 shows a first portion 200-0 and second portion 200-1 of IC device 200. Such device portions 200-0/1 may or may not be in a same cross sectional plane. Portion 200-0 shows how first IGFET rows 214 can each be electrically connected to a first conductive line 210-0 (through a direct connection or through a via or contact). Each first through via 212-0 can be electrically connected between a first conductive line 210-0 and first terminal 208-0 (through back side routing 224). Portion 200-1 shows how second IGFET rows 216 can be electrically connected to a second terminal 208-1 with second conductive lines 210-1, second through vias 212-1, and backside routing 224. It is understood that second conductive lines 210-1 in first portion 200-0 can be electrically connected to second through vias not shown by the cross sectional plane. Similarly, first conductive lines 210-0 in second portion 200-1 can be electrically connected to first through vias not shown by the cross sectional plan.

In some embodiments, a first terminal 208-0 can receive a first power supply (e.g., VDD or VSS) and a second terminal 208-1 can receive a second power supply (e.g., VSS or VDD). In this way, different power supply voltages can be provided to rows of IGFETs of different conductivity types.

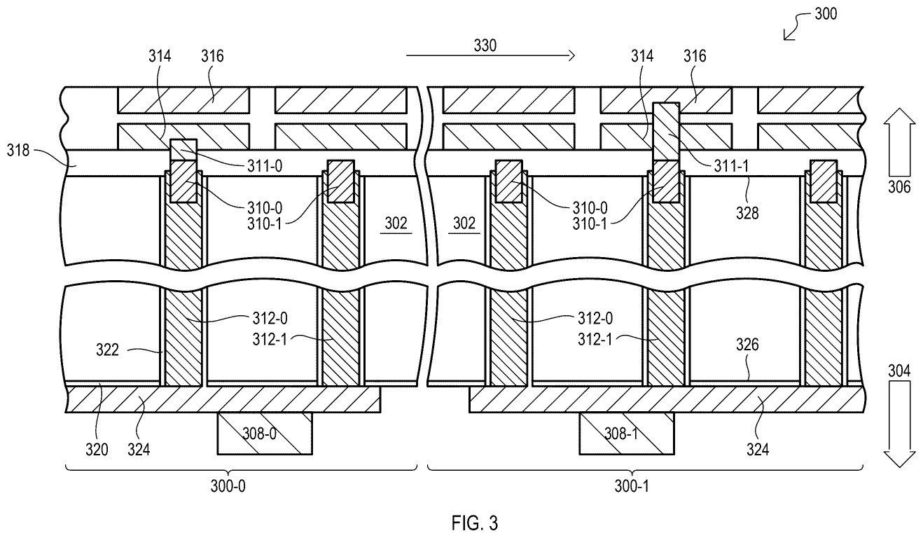

Referring to FIG. 3, an IC device 300 according to another embodiment is shown in a side cross sectional view. In some embodiments, IC device 300 can be one implementation of that shown in FIG. 1. IC device 300 can include items like those of FIG. 2, and such like items are referred to by the same reference character but with the leading digit being a “3” instead of a “2”.

FIG. 3 shows rows of second IGFETs 316 formed over rows of first IGFETs 314. In some embodiments, such an arrangement can result in stacked pairs of IGFETs, with an IGFET of a second conductivity type being formed over an IGFET of a first conductivity type.

Portion 300-0 shows how first IGFET rows 314 can be electrically connected to a first terminal 308-0 by way of a first contact (and/or via) structure 311-0, first conductive line 310-0, first through via 312-0 and backside routing 224. Portion 300-1 shows how second IGFET rows 316 can be electrically connected to a second terminal 308-1 by way of a second contact/via structure 311-1, second conductive line 310-1, second through via 312-1 and backside routing 324. It is understood that first conductive lines 310-0 and second conductive lines 310-1 that do not show respective first and second contact/via structures 311-0/1 in the side cross sectional view of FIG. 3, may respectively include first and second contact/via structures 311-0/1 at spaces into the plane offset from through vias 312-0/1.

Having described IC devices with IGFET rows of different types, and backside conductive connections to such rows, methods of forming such devices will now be described.

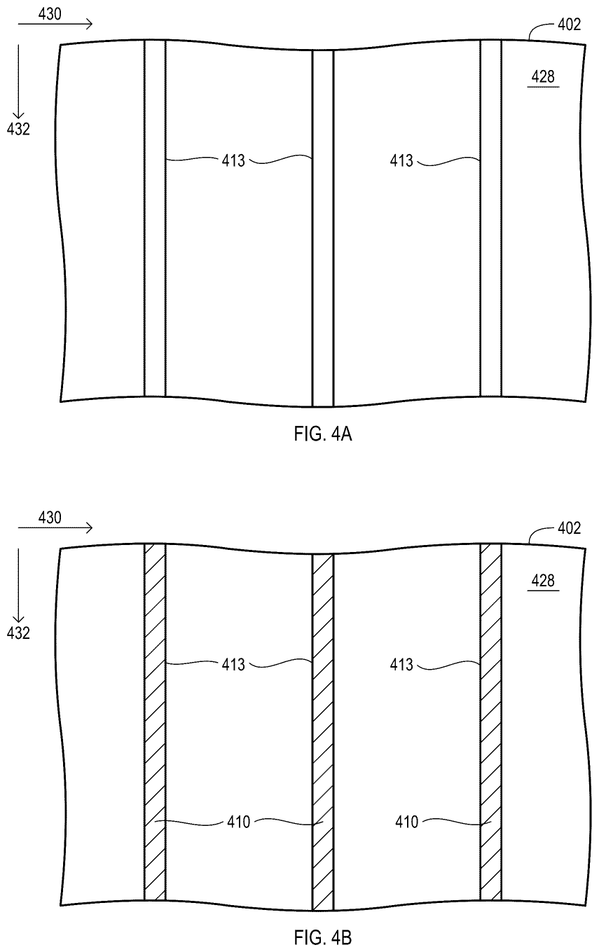

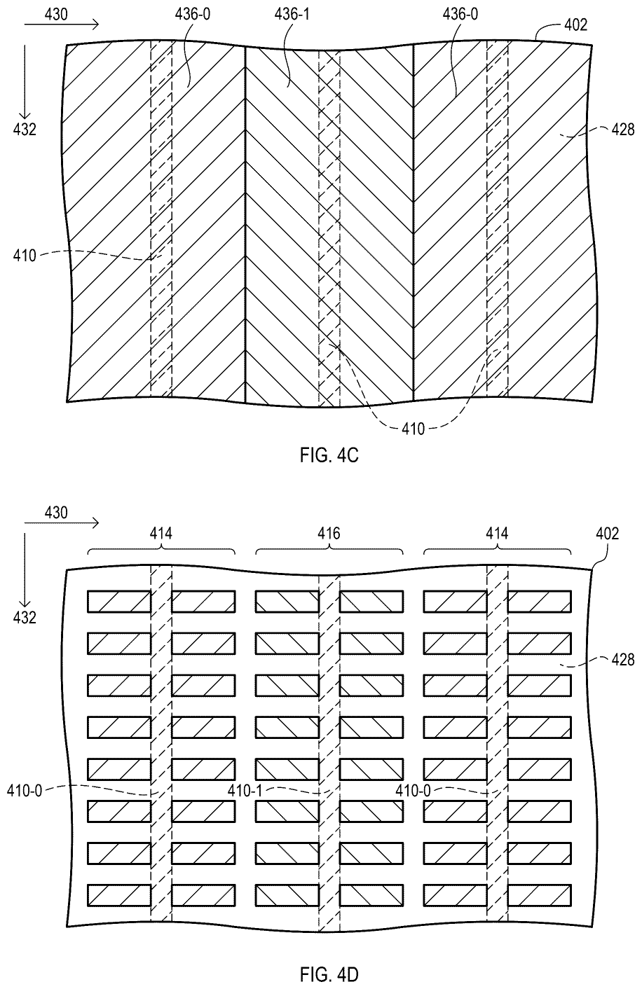

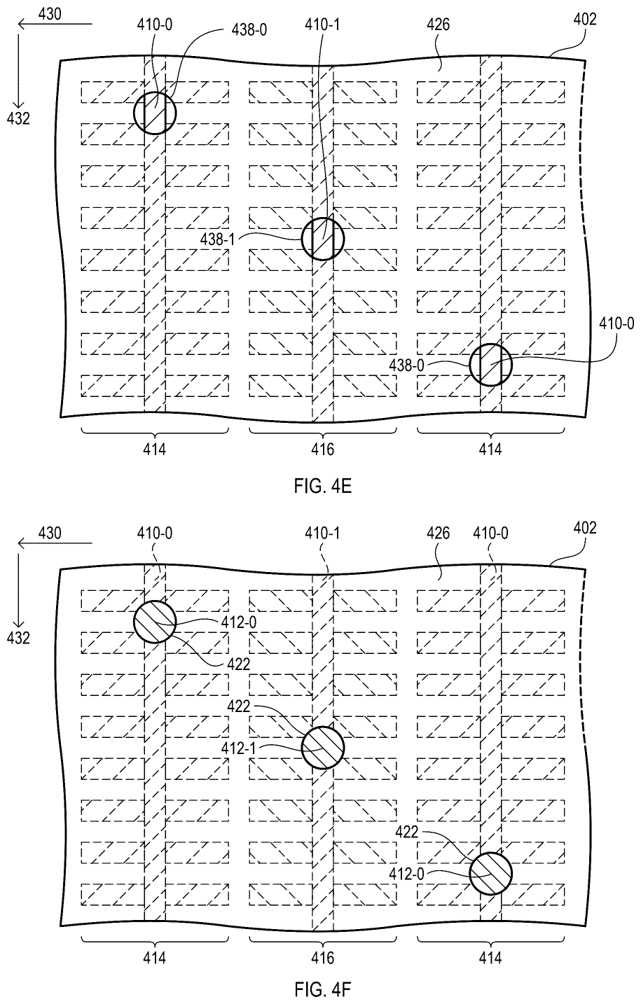

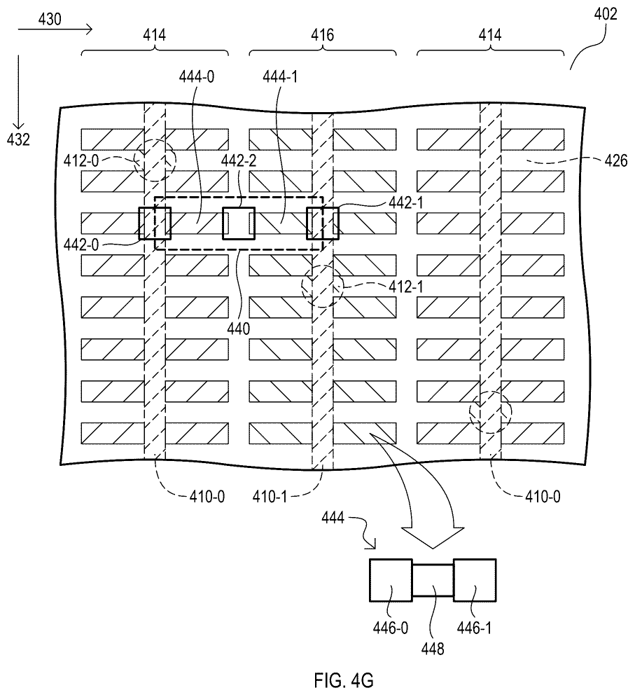

FIG. 4A is a view showing a second (e.g., top) surface 428 of a substrate 402. Trenches 413 can be formed in second surface 428 that can extend in a first direction 432 and be parallel to one another in a second direction 430. The formation of trenches 413 can be made any etching method suitable for the substrate employed, including pattern and etch steps.

FIG. 4B is a view of a second surface 428 after the formation of buried conductive lines 410 within trenches 413. Buried conductive lines 410 can be formed with any suitable fabrication steps, including, but not limited to, damascene approaches that form one or more layers within trenches and then planarize a surface. Conductive lines 410 can extend in first direction 432 and be parallel to one another in a second direction 430. In some embodiments, conductive lines 410 can be insulated from a substrate 402 by an insulating material/layer (not shown).

FIG. 4C is a view of a second surface 428 after the formation of first sheets 436-0 and second sheets 436-1. Sheets 436-0/1 can be layers that can be patterned in the formation IGFET rows of different conductivity types. Sheets 436-0/1 can be formed in any suitable way, including, but not limited to, depositing a material, and then doping the material to different conductivity types to form sheets 436-0/1 or depositing such sheets separately. It is understood that sheets 436-0/1 can be formed from multiple layers or a single layer. Sheets 436-0/1 can be patterned to form part of an IGFET (e.g., channels) or substantially all of an IGFET (e.g., channels, source, drain). In some embodiments, sheets 436-0/1 can be formed over one or more insulating layers (not shown) above conductive lines 410. In some embodiments, sheets 436-0/1 can be formed in contact with one or more conductive lines 410.

FIG. 4D is a view of a second surface 428 after a patterning of first and second sheets to create first rows of IGFETs 414 and a second row of IGFETs 416. In the embodiment shown, a location of a conductive line can result in the buried conductive line being a first conductive line 410-0 (e.g., a conductive line formed below a first row of IGFETs 414) or a second buried conductive line 410-1 (e.g., a conductive line formed below a second row of IGFETs 416).

FIG. 4E is a view of a first surface 426 opposite to second surface 428 shown in FIG. 4A to 4D after the formation of first through hole 438-0 and second through holes 438-1. First through holes 438-0 can be formed from first surface 426, through substrate 402, to expose first buried conductive lines 410-0. Similarly, second through holes 438-1 can be formed from first surface 426, through substrate 402, to expose second buried conductive lines 410-1. Through holes 438-0/1 can be formed in any suitable fashion, including but not limited to a pattern and etch step that is highly selective to a substrate material over material(s) of conductive lines 410-0/1.

FIG. 4F is a view of a first surface 426 after the formation of first through vias 412-0 in first through hole 438-0 and second through vias 412-1 in second through holes 438-1. In some embodiments, first through vias 412-0 can make conductive contact with first buried conductive lines 410-0, and second through vias 412-1 can make conductive contact with second buried conductive lines 410-1. In some embodiments, first and second through vias 412-0/1 can include a via insulator 422 that can insulate the conductive material of the through via 412-0/1 from a substrate 402.

FIG. 4G is a view toward a second surface 426 after the formation of a logic circuit 440 with IGFETs of a first conductivity type 444-0 and IGFETs of a second conductivity type 444-1 that can receive power via first and second conductive lines 410-0/1. As shown by IGFET 444, each IGFET (444-0, 444-1) can include a first source/drain (S/D) 446-0, a second S/D 446-1, and channels 448. As will be described in more detail herein, channels 448 can take any of a number of forms. Further, it is understood that first and second S/D 446-0/1 can have been formed after a patterning of the sheets, including but not limited to one or more etch and replace steps.

Referring still to FIG. 4G, a logic circuit 440 can be formed with portions of a first row of IGFETs 414 and a portion of a second row of IGFETs 416. A first contact 442-0 can provide a conductive path between a first S/D of first IGFET 444-0 and a first buried conductive line 410-0. In this way, logic circuit 440 can be provided with a first power supply voltage via first through via 412-0. A second contact 442-1 can provide a conductive path between a first S/D of second IGFET 444-1 and a second buried conductive line 410-1. In this way, logic circuit 440 can be provided with a second power supply voltage via second through via 412-1. In the particular embodiment shown, a third contact 442-2 can provide a conductive path between second S/Ds of first IGFET 440-0 and second IGFET 440-1. It is understood that while logic circuit 440 is shown with two IGFETs, a logic circuit can include any number of IGFETs according to the desired application, including but not limited to the logic circuit type and/or desired logic circuit performance.

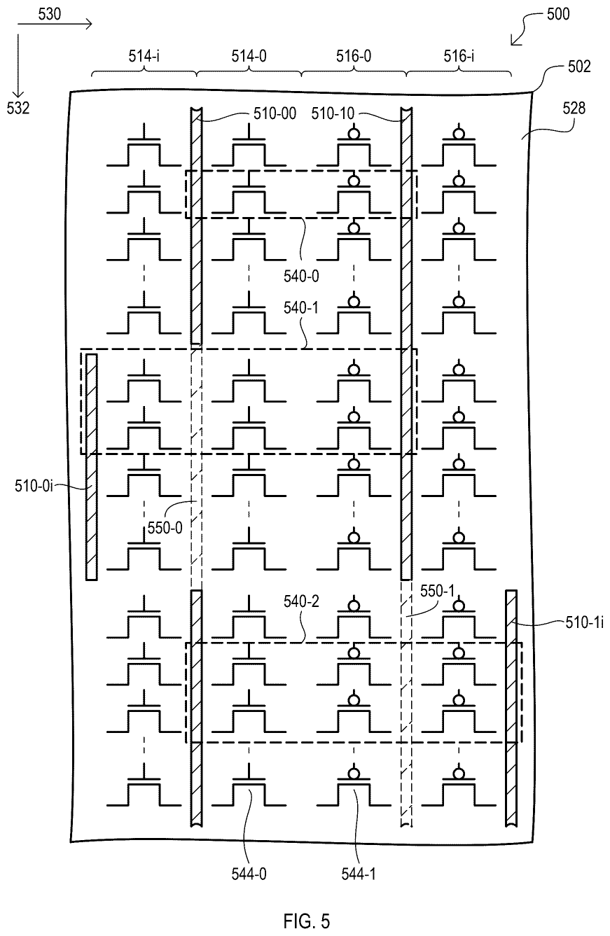

FIG. 5 is a top plan view of an IC device 500 according to another embodiment. FIG. 5 can include items like those of FIG. 4G, and such like items are referred to by the same reference character but with the leading digit being a “5” instead of a “4”. FIG. 5 shows first transistor rows 514-0 to 514-i, which can be formed of n-type IGFETs, and second transistor rows 516-0 to 516-i, which can be formed of p-type IGFETs. FIG. 5 also shows first buried conductive lines 510-00 to 510-0i, which can provide a first power supply (e.g., VSS), and second buried conductive lines 510-10 to 510-1i, which can provide a second power supply (e.g., VDD).

FIG. 5 shows how logic circuits can be formed with portions of first and second IGFET rows, where such first and second rows are situated between first and second buried conductive lines. Logic circuit 540-0 can include portions of a first row 514-0 and a second row 516-0. Logic circuit 540-1 can include portions from first rows 514-0 to 514-i, and a portion of second row 516-0 situated between first buried conductive line 510-0i and second buried conductive line 510-10. First rows 514-0 to 514-i can include two or more adjacent first rows. Logic circuit 540-2 can include portions from first rows 514-0 and portions of second rows 516-0 to 516-i situated between first buried conductive line 510-00 and second buried conductive line 510-1i. Second rows 516-0 to 516-i can include two or more adjacent second rows.

In some embodiments, logic circuits can include region 550-0 and 550-1 in line with buried conductive lines 510-00 and 510-10, respectively. In some embodiments, regions 550-0/1 can be the same as their respective buried conductive lines. In such an arrangement, region 550-0 can carry a first power supply voltage, but not provide such a first power supply voltage to logic circuit 540-1. Logic circuit 540-1 may receive a first power supply voltage from first buried conductive line 510-0i. Similarly, region 550-1 can provide a second power supply voltage, but not provide such a second power supply voltage to logic circuit 540-2. Logic circuit 540-2 may receive a second power supply voltage from second buried conductive line 510-1i. Alternatively, regions 550-0 and/or 550-1 may be breaks in buried conductive lines, there being no conductive material and/or no trench at such regions 550-0/1. Alternatively, regions 550-0 and/or 550-1 can be formed in a same manner as first and second buried conductive lines 510-00/01, 510-10/1i, but provide a function other than providing a power supply. Such other functions can include, but are not limited to, local interconnect between transistors of the respective logic circuit or an input or output node for the circuits. In the former case (i.e., local interconnect), a region 550-0/1 may not be connected to a through via. In the latter case (i.e., I/O node), a region 550-0/1 can be connected to an I/O through via.

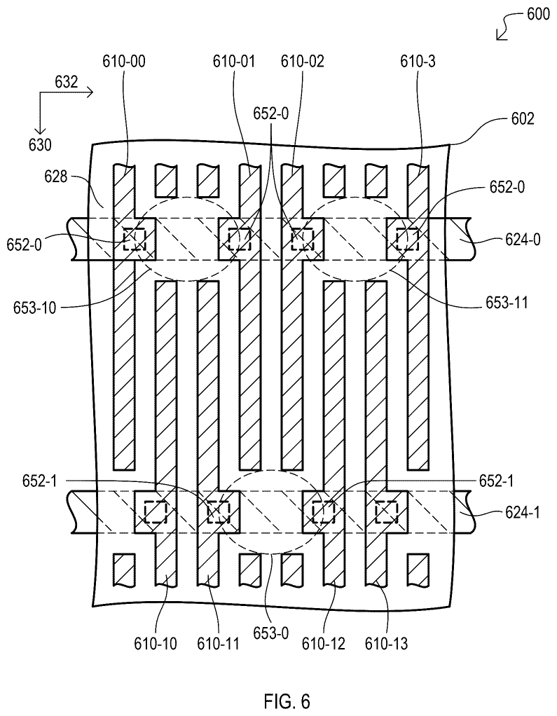

FIG. 6 a top view of an IC device 600 according to another embodiment. FIG. 6 can include items like those of FIG. 4G, and such like items are referred to by the same reference character but with the leading digit being a “6” instead of a “4”. FIG. 6 shows first buried conductive lines 610-00, -01, -02, -03 and second buried conductive lines 610-10, -11, -12, -13 formed in a second (e.g., top) surface 628 of a substrate. First and second buried conductive lines 610-00 to -13 can extend in a first direction 630 and be parallel to one another in a second direction 632. First buried conductive lines 610-01/02 can have a first opening 653-0, which can be a break in the first direction. Similarly, second buried conductive lines 610-10/11 can have a second opening 653-10, and buried conductive lines 610-12/13 can have a second opening 653-11.

Within all, or a portion of such openings 653-0/10/11, contacts to through vias can be made, with such through vias being in contact with backside routing members 624-0/1. In the embodiment shown, first opening 653-0 can include second via contacts 652-1, which can provide a conductive connection to second through vias (not shown) that extend into the view of FIG. 6, and make a conductive connection to backside routing structure 624-1. Second openings 652-10/11 can include first via contacts 652-0, which can provide a conductive connection to first through vias, and make a conductive connection to backside routing structure 624-0. First via contacts 652-0 (and hence corresponding first through vias) can be aligned with one another in the second direction 632. Second via contacts 652-1 (and hence corresponding second through vias) can be aligned with one another in the second direction 632, but offset from first via contacts/through vias in the first direction 630.

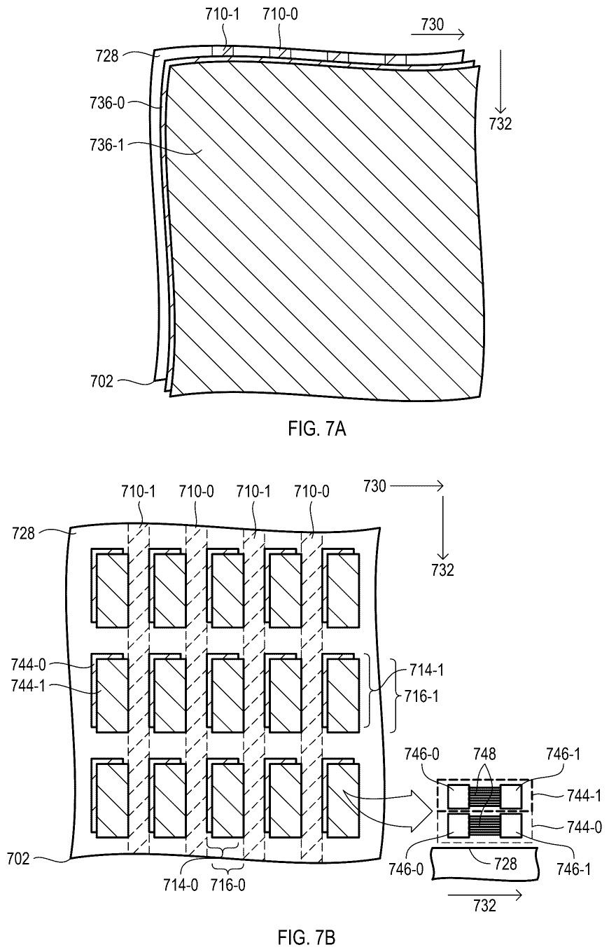

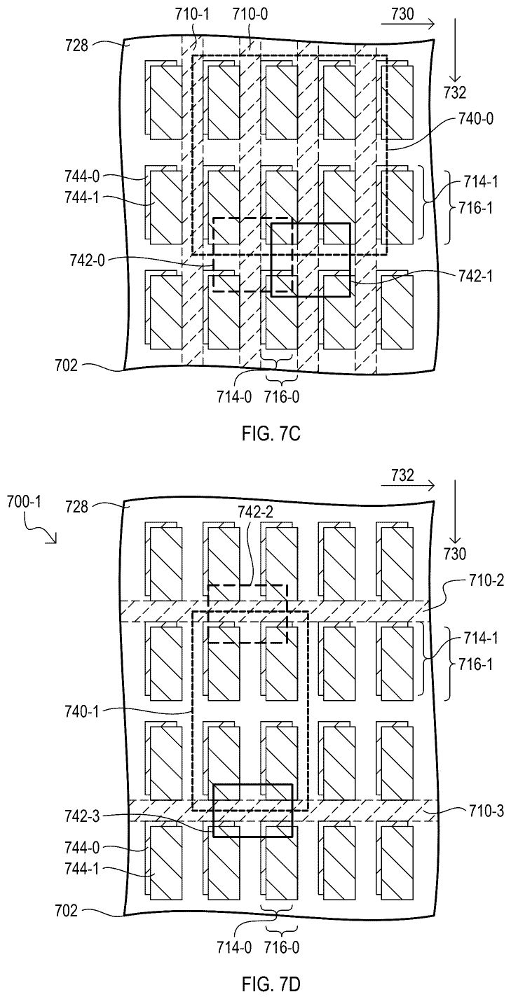

FIGS. 7A to 7C are top plan views showing the formation of an IC device according to another embodiment. Referring to FIG. 7A, first IGFET sheet 736-0 can be formed over a second (e.g., top) surface 728 of a substrate 702. In some embodiments, a first IGFET sheet 736-0 can include multiple layers formed on top of one another, including semiconductive and/or conductive layers separated by one or more insulating layers. A first IGFET sheet 736-0 can serve to form part or all of first type transistors in a first row, and can be formed over a surface insulator (not shown). A second IGFET sheet 736-1 can be formed over first IGFET sheet on an inter-layer device insulator (not shown). In some embodiments, a second IGFET sheet 736-1 can include multiple layers formed on top of one another, including semiconductive and/or conductive layers separated by one or more insulating layers. A second IGFET sheet 736-1 can serve to form part or all of second type transistors of second rows.

Referring to FIG. 7B, first and second IGFET sheets can be processed to create IGFET pairs of opposite conductivity type, each including a first (e.g., bottom) IGFET of a first conductivity type 744-0, and second (e.g., top) IGFET of a second conductivity type 744-1. Such processing can include any suitable patterning steps, as well as other transistor formation steps including, forming a gate insulator, surrounding gate, and source and drain formation. Stacked IGFET pairs 744-0/1 can be conceptualized as forming second rows 716-0 over first rows 714-0 in a first direction 732 or stacked second and first rows 716-1/714-1 in a second direction 730. In the embodiment shown, IGFET gates 748 can be disposed between corresponding first and second S/Ds 746-0/1 in a same direction as first and second conductive lines 710-0/1 (i.e., first direction 732).

Referring to FIG. 7C, a first contact 742-0 can provide a first power supply voltage from a first buried conductive line 710-0 to one or more first (i.e., bottom) transistors 744-0. In the embodiment shown, first contact 742-0 can provide such a supply to four first IGFETS 744-0. However, in other embodiments, a first contact can provide a power supply to a greater or smaller number of first IGFETs 744-0, including a single such IGFET. It is understood that a first contact 742-0 can be formed, all or in part, before, after or during the formation of first and second transistors 744-0/1. A second contact 742-1 can provide a second power supply voltage from a second buried conductive line 710-1 to one or more second (i.e., top) transistors 744-1. In the embodiment shown, second contact 742-1 can provide such a supply to four second IGFETS 744-1. In some embodiments, a second contact 742-1 can be formed after the formation of first and second transistors 744-0/1. A logic circuit 740-0 can be formed by portions of first and second rows 714-0/716-0, 714-1, 716-1.

FIG. 7D is a top plan view of an IC device 700-1 according to another embodiment. An IC device 700-1 can include items like those of FIG. 7C, and such like items are referred to by the same reference character. In the embodiment shown, first and second buried conductive lines 710-2/710-3 can be disposed in a second direction 732. Consequently, IGFET gates can be disposed in a direction perpendicular to first and second conductive lines 710-2/3.

Referring still to FIG. 7D, a first contact 742-2 can provide a first power supply voltage from a first buried conductive line 710-2 to one or more first transistors 744-0. A first contact 742-2 can be formed, all or in part, before, after or during the formation of first and second transistors 744-0/1. A second contact 742-3 can provide a second power supply voltage from a second buried conductive line 710-3 to one or more second transistors 744-1. A logic circuit 740-1 can be formed by portions of first and second rows 714-0/716-0,

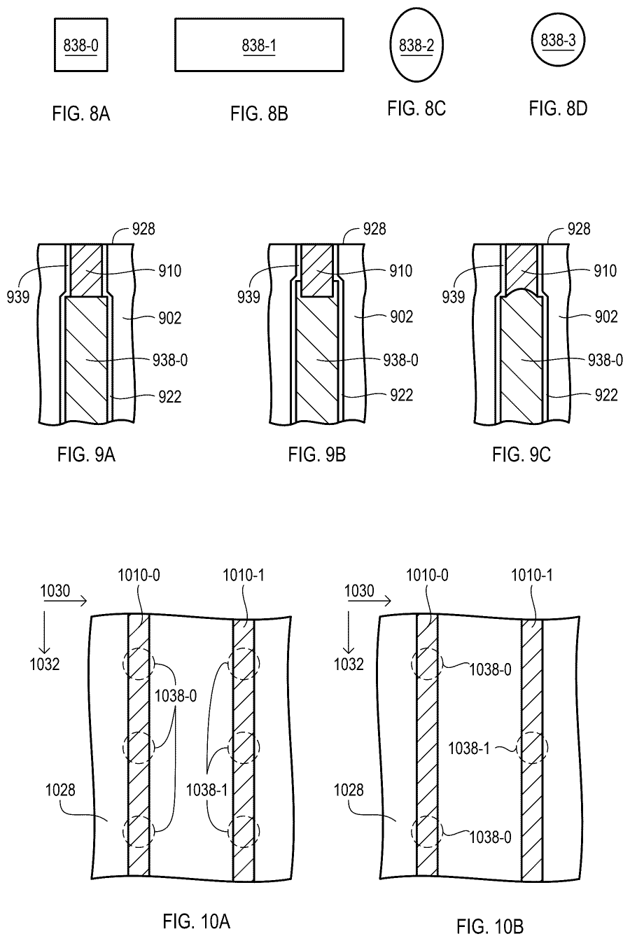

According to embodiments, through vias can take any suitable form, being formed of one or more layers, one or more materials, and one or more shapes. FIGS. 8A to 8D show cross sectional views of through vias that can be included in embodiments. FIG. 8A shows a square shaped via cross sectional shape. FIG. 8B shows a rectangular shaped via cross sectional shape. FIG. 8C shows an ellipsoid shaped via cross sectional shape. FIG. 8D shows a circular shaped via cross sectional shape. However, such shapes should not be construed as limiting.

In some embodiments, through vias can make direct conductive contact with one or more buried conductive lines. According to embodiments, through vias can carry any suitable voltage or signal through a substrate to circuits at one side of an IC device, including but not limited to, a power supply voltage, an input signal to an IC device, an output signal from an IC device, or a reference voltage. In some embodiments, a through via can carry a voltage/signal through one IC device to one or more other IC devices. FIGS. 9A to 9C are side cross sectional views showing conductive contacts between through vias and buried conductive lines that can be included in embodiments. FIG. 9A shows an arrangement in which a through via 938-0 can make direct contact with a bottom side of a buried conductive line 910. In some embodiments, such an arrangement can arise from a through via hole etch step that is not selective between a substrate 902 and buried conductive line 910. FIG. 9B shows an arrangement in which a through via 938-0 can make direct contact with a bottom side and sides of a buried conductive line 910 which may reduce contact resistance due to the increased surface area at the connection interface. In some embodiments, such an arrangement can arise from a through via hole etch step that is selective to a substrate 902 over a buried conductive line 910. FIG. 9C shows an arrangement in which a through via 938-0 can extend into a bottom side of a buried conductive line 910 which may reduce contact resistance due to the increased surface area at the connection interface. In some embodiments, such an arrangement can arise from a through via hole etch step that is selective to a buried conductive line 910 over a substrate 902. While FIGS. 9A to 9C show buried conductive lines 910 that have top surfaces coplanar with a front surface 928, alternate embodiments can include buried conductive lines with portions that extend above a front surface 928 and/or buried conductive lines with top surfaces that are located below a top surface 928. In some embodiments, a via insulator 922 can be formed between through via 938-0 and a substrate 902. In some embodiments, a line insulator 939 can be formed between buried conductive line 910 and a substrate 902.

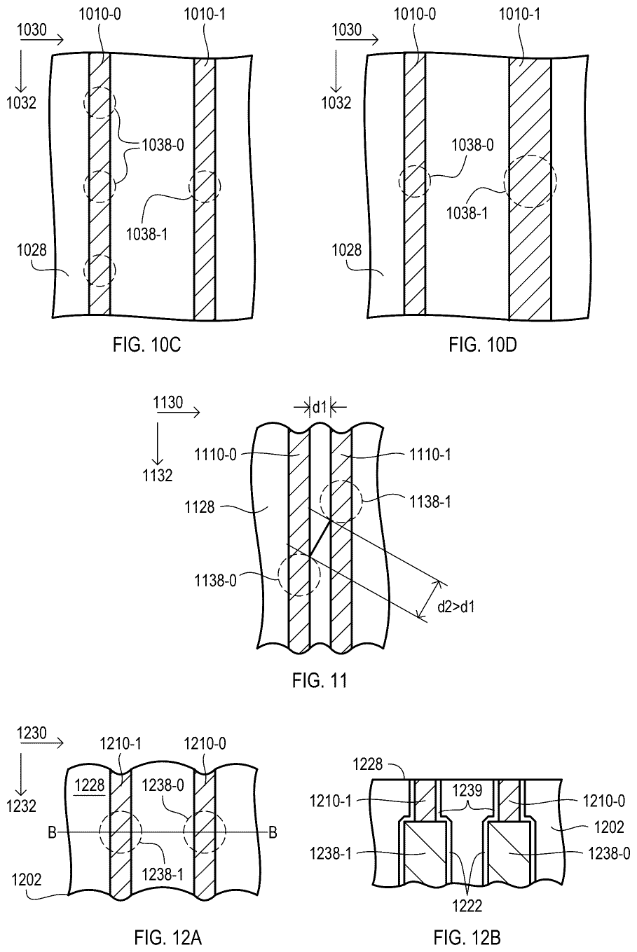

FIGS. 10A to 10D are top views showing locations of through vias with respect to buried conductive lines, and to one another, according to embodiments. FIGS. 10A to 10D show first and second conductive lines 1010-0/1 formed in a second (e.g., front) surface 1028 of a substrate. First through vias 1038-0 can have a conductive connection to first conductive line 1010-0 below a second surface 1028. Second through vias 1038-1 can have a conductive connection to second conductive line 1010-1 below a second surface 1028. In some embodiments, first and second conductive lines 1010-0/1 can carry a same supply voltage. In some embodiments, first and second conductive lines 1010-0/1 can carry different supply voltages.

FIG. 10A shows first through vias 1038-0 that can be aligned with one another in a first direction 1032 and second through vias 1038-0 aligned with one another in the first direction 1032. First through vias 1038-0 can also be aligned with second through vias 1038-1 in a first direction 1030 perpendicular to a second direction 1032. FIG. 10B shows second through vias 1038-1 that can be offset from first through vias 1038-0 in a first direction 1032. FIG. 10C shows first through vias 1038-0 having a greater frequency (e.g., smaller separation from one another) than second through vias 1038-1 in a first direction 1032. FIG. 10D shows second through vias 1038-1 having a greater cross sectional area than first through vias 1038-0.

FIG. 11 is a top view showing locations of through vias with respect to buried conductive lines according to a further embodiment. FIG. 11 includes items like those of FIGS. 10A to 10D, and such like items are referred to by the same reference character but with the leading digits being “11” instead of “10”. In FIG. 11, buried conductive lines 1110-0/1 can extend in a first direction 1132 and be adjacent to one another in a second direction 1130. First and second buried conductive lines 1110-0/1 can have a minimum separation distance d1. A minimum separation distance between adjacent through vias 1138-0/1 (i.e., d2) can be greater than d1. In this way, through via process margin may be improved and capacitance coupling may be reduced.

FIGS. 12A and 12B show via connections to buried conductive lines according to an embodiment. FIG. 12B is a cross sectional view of FIG. 12A taken along line B-B. FIGS. 12A and 12B show first and second buried conductive lines 1210-0/1 formed in a second surface 1228 of a substrate 1202, as well as first and second through vias 1238-0/1. First and second through vias 1238-0/1 can be centered and in contact with first and second buried conductive lines 1210-0/1. In some embodiments, buried conductive lines 1210-0/1 can be isolated from substrate by line insulator 1239. In some embodiments, through vias 1238-0/1 can be isolated from substrate by via insulator 1222.

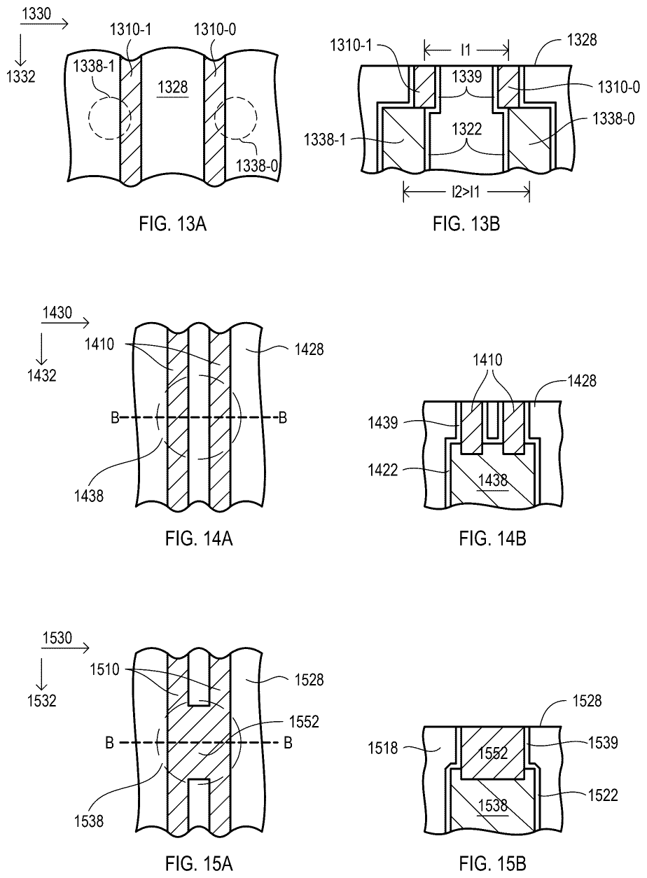

FIGS. 13A and 13B show via connections to buried conductive lines according to another embodiment. FIGS. 13A/B shows items like those of FIGS. 12 A/B and such like items are shown by the same reference character but with the leading digits being a “13” instead of a “12”. FIGS. 13A and 13B show first and second through vias 1338-0/1 offset from (i.e., not centered), but in contact with first and second buried conductive lines 1310-0/1. In such an arrangement, a distance between first and second through vias 1338-0/1 (12) can be greater than a distance between first and second buried conductive lines 1310-0/1. In this way, through via process margin may be improved and capacitance coupling may be reduced.

FIGS. 14A and 14B show a same via connection to multiple buried conductive lines according to another embodiment. FIGS. 14A/B shows items like those of FIGS. 12A/B and such like items are shown by the same reference character but with the leading digits being a “14” instead of a “12”. FIGS. 14A and 14B show a through via 1438 in contact with two, adjacent buried conductive lines 1410. Alternate embodiments can include through vias that make contact with more than two conductive lines. In this way, adjacent buried conductive lines 1410 may provide double the current density by connecting both to provide a power supply voltage, an input signal, or receive an output signal to and from a logic circuit.

FIGS. 15A and 15B show a via connection to widened portion in a buried conductive line layer according to an embodiment. FIGS. 15A/B shows items like those of FIGS. 12A/B and such like items are shown by the same reference character but with the leading digits being a “15” instead of a “12”. FIGS. 15A and 15B show a through via 1538 in contact with a wide portion 1552 (i.e., wide in a second direction 1530) of a buried conductive line structure 1510. While FIGS. 15A/B show a wide portion 1552 contiguous with two buried conductive lines 1510, alternate embodiments can include a wide portion contiguous with one buried conductive line and/or contiguous with more than two buried conductive lines. In the former case, a wide portion may extend into an opening or break in adjacent buried conductive lines (e.g., see FIG. 6). In this way, adjacent buried conductive lines 1410 may provide double the current density by connecting both to provide a power supply voltage, an input signal, or receive an output signal to and from a logic circuit while contact resistance from the through via 1538 to the conductive lines 1510 may be reduced.

While embodiments can include first and/or second buried conductive lines connected to through vias to power rows of IGFETs, embodiments may also include similar structure for the transport of input signals to, or output signals from an IC device.

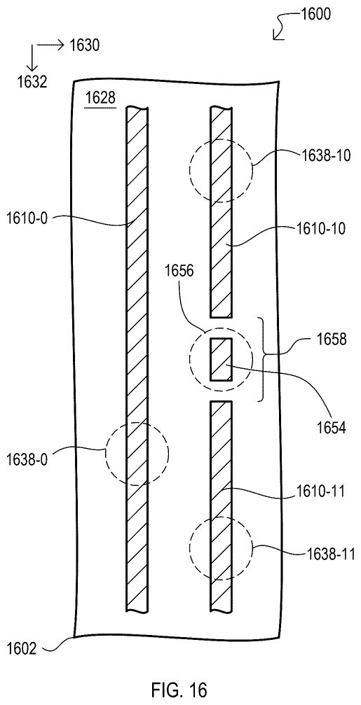

FIG. 16 is a top plan view of an IC device 1600 showing a first buried conductive line 1610-0, second buried conductive line 1610-10, third buried conductive line 1610-11, formed in a front surface 1628 of a substrate 1602. Second and third buried conductive lines 1610-10/11 can be adjacent to first buried conductive line 1610-0 in a first direction 1630. Second buried conductive line 1610-10 can be aligned with third buried conductive line 1610-11 in a first direction 1632. First, second and third buried conductive lines 1610-0, -10, -11 can have conductive connections to first, second and third through vias 1638-0, -10, -11, respectively, formed in a substrate 1602.

Referring still to FIG. 16, an input or output (I/O) conductive structure 1654 can be formed in an opening 1658 between second and third buried conductive lines 1638-10/11. In some embodiments, an I/O conductive structure 1654 can be formed from same conductive layer(s) as first, second and third buried conductive lines 1610-0, -10, -11. In some embodiments, an I/O conductive structure 1654 can have a same width in the second direction 1630 as second and third buried conductive lines 1610-10/11. An I/O via 1656 can have a conductive connection to conductive structure 1654. An I/O conductive structure 1654 and I/O via 1656 can carry an input signal to circuits formed with IGFET rows and/or carry an output signal from IGFET rows.

Embodiments may also include “dummy” structures formed from a same layer as buried conductive lines. Such dummy conductive structures may not carry electrical signals. In some embodiments, such dummy structures can serve to conduct heat from a first side of an IC device to a second side of an IC device, or vice versa.

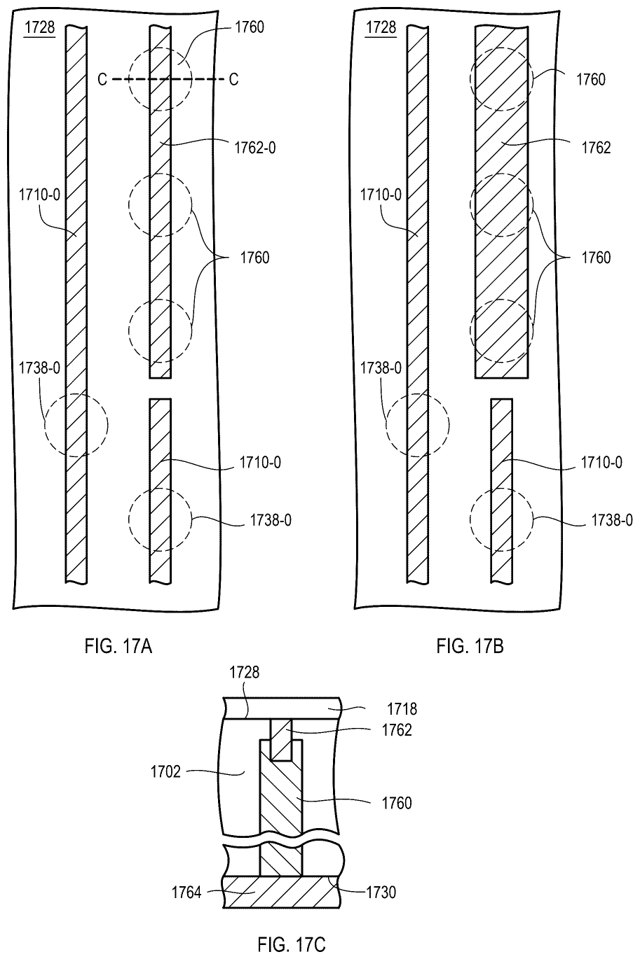

FIGS. 17A to 17C are diagrams showing dummy structures that can be included in embodiments. FIG. 17A shows buried conductive lines 1710-0 and a dummy structure 1762-0 formed in a front surface 1728 of a substrate 1702. In some embodiments, a dummy structure 1762-0 can be formed from same conductive layer(s) as buried conductive lines 1710-0. In the embodiment shown, a dummy structure 1762-0 can have a same width in a second direction 1730 as buried conductive lines 1710-0. One or more dummy vias 1760-0 can have a thermally conductive connection to dummy structure 1762-0.

FIG. 17B shows an arrangement like that of FIG. 17A, but with a dummy conductive structure 1762-1 having a greater width in a second direction 1730 than buried conductive lines 1710-0.

FIG. 17C is a side cross sectional view of a dummy via 1760 in thermal contact with a dummy structure 1762. A dummy via 1760 can have a thermal connection to a heat sink 1764 structure formed on a first (e.g., back) surface 1764 of a substrate 1702.

In this way, structures created while forming buried conductive lines for carrying electrical signals, such as power supply voltages, that are not used and/or not needed to carry electrical signals can serve as heat conducting paths from one surface of an IC device to an opposing surface.

Embodiments can include IGFETs of any suitable type and construction, capable of making a conductive connection to buried conductive lines formed in a substrate below. Various examples of IGFET types and configurations will now be described. Such examples should not be construed as limiting.

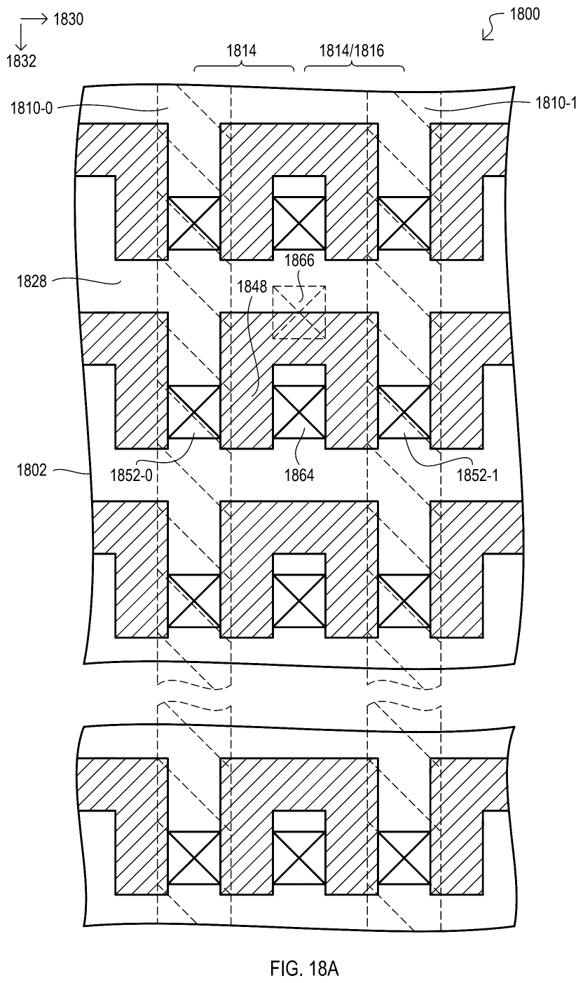

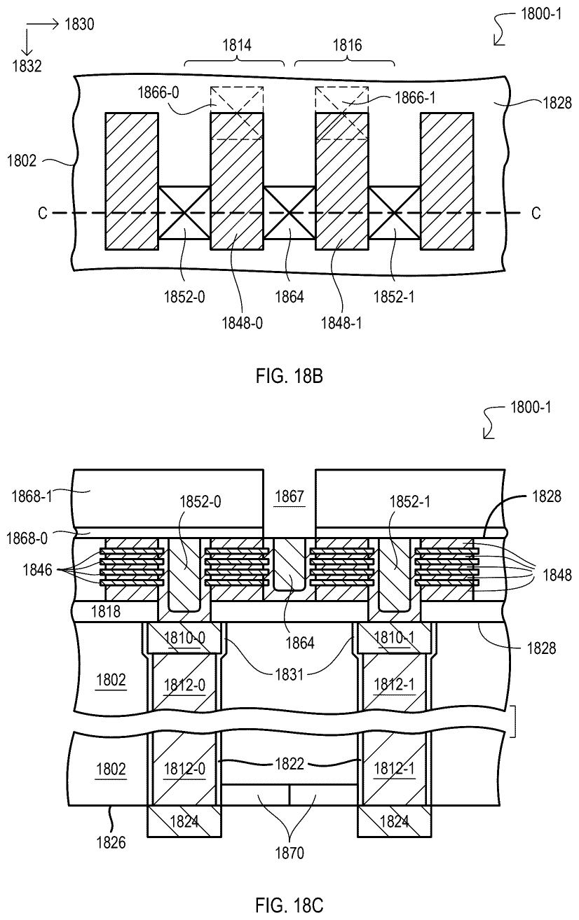

FIG. 18A is a top plan view of an IC device 1800 according to an embodiment. An IC device 1800 can include first and/or second buried conductive lines 1810-0/1 formed in a second (e.g., top) surface 1828 of a substrate. In embodiments, such buried conductive lines 1810-0/1 can carry a same power supply voltage. In such embodiments, adjacent transistor rows can be first type rows 1814/1814 of transistors of one conductivity type. In other embodiments, first buried conductive line 1810-0 can carry one power supply voltage while second buried conductive line 1810-1 can carry a different power supply voltage. In such embodiments, adjacent transistor rows can be first and second rows of different conductivity types (i.e., 1814 and 1816).

FIG. 18A shows a gate structure 1848 formed between a first via contact 1852-0, a drain contact 1864, and a second via contact 1852-1. A gate contact 1866 can be formed to provide a controlling voltage to gate structure 1848. A first via contact 1852-0 can enable a conductive connection to first buried conductive line 1810-0 which can be connected to a through via to provide a power supply voltage to a source of an IGFET. A second via contact 1852-1 can enable a conductive connection to second buried conductive line 1810-1 which can be connected to through via to provide a power supply voltage to a source of another IGFET. A drain contact 1864 can provide a common drain contact for two IGFETs. It is understood that gate structure 1848 can include a gate that contiguously surrounds multiple channels for one IGFET between first via contact 1852-0 and drain contact 1864, and contiguously surrounds multiple channels for another IGFET between second via contact 1852-1 and drain contact 1864.

In some embodiments, a gate structure 1848 can be a gate for two IGFETs of a same conductivity type, with first and second via contacts 1852-0/1 being connected to a same power supply, and a first IGFET formed between first via contact 1852-0 and drain contact 1864. A second IGFET can be formed between second via contact 1852-1 and drain contact 1864. In other embodiments, a gate structure 1848 can be a gate for two IGFETs of different conductivity types, in which case first via contact 1852-0 can carry a first power supply voltage, while second via contact 1852-1 carries a second power supply voltage.

FIG. 18B is a top plan view of a IC device 1800-1 according to another embodiment. An IC device 1800-1 can have items like those of FIG. 18A, and such like items are referred to by the same reference characters. FIG. 18B can differ from FIG. 18A in that a first gate 1848-0 with a first gate contact 1866-0 can be formed between first via contact 1852-0 and drain contact 1864. A second gate 1848-1 with a first gate contact 1866-1 can be formed between second via contact 1852-1 and drain contact 1864. First and second IGFET rows 1814/1816 can extend in a second direction 1832. IGFETs of row 1814 can be of one conductivity type. IGFETs of row 1816 can be of the same conductivity type (i.e., first and second via contacts 1852-0/1 receive a same power supply voltage) or can be different conductivity types (i.e., first and second via contacts 1852-0/1 receive different power supply voltages).

FIG. 18C is a side cross sectional view of IC device 1800-1 taken along line C-C of FIG. 18B. FIG. 18C shows how a gate 1848 can surround channels 1846 that can extend between via contacts 1852-0/1 and drain contact 1864. A contact opening 1867 is shown through top insulating layers 1868-0/1 to drain contact 1864 which can be used to provide an interconnect connection to drain contact 1864. IGFETs can be formed on a front side insulator 1818, which can be formed on a second surface 1828 of a substrate 1802.

Referring still to FIG. 18C, first via contact 1852-0 can be in contact with first buried conductive line 1810-0. First buried conductive line 1810-0 can be in contact with first through via 1812-0, which can extend through substrate 1802 and make contact with back side routing 1824. Second via contact 1852-1 can be in contact with second buried conductive line 1810-1, which can be in contact with second through via 1812-1, which can make contact with back side routing 1824. Backside routing 1824 can be formed on a first surface 1826 of substrate, can provide a conductive path to one or more terminals configured to enable connection to the IC device (not shown). In the embodiment shown, through vias 1812-0/1 can be insulated from a substrate with a via insulator 1822. Buried conductive lines 1810-0/1 can be insulated from a substrate 1802 with a line insulator 1831.

Referring still to FIG. 18C, one or more back side circuit elements 1870 can be formed in a first surface 1826 of a substrate 1802. As is described in more detail herein, back side circuit elements 1870 can take various forms, including but not limited to, one or more passive circuit elements, one or more active circuits elements (e.g., IGFET, bipolar transistor, JFET), or one or more circuits (e.g., ESD protection circuit, power gating circuit, output driver circuit).

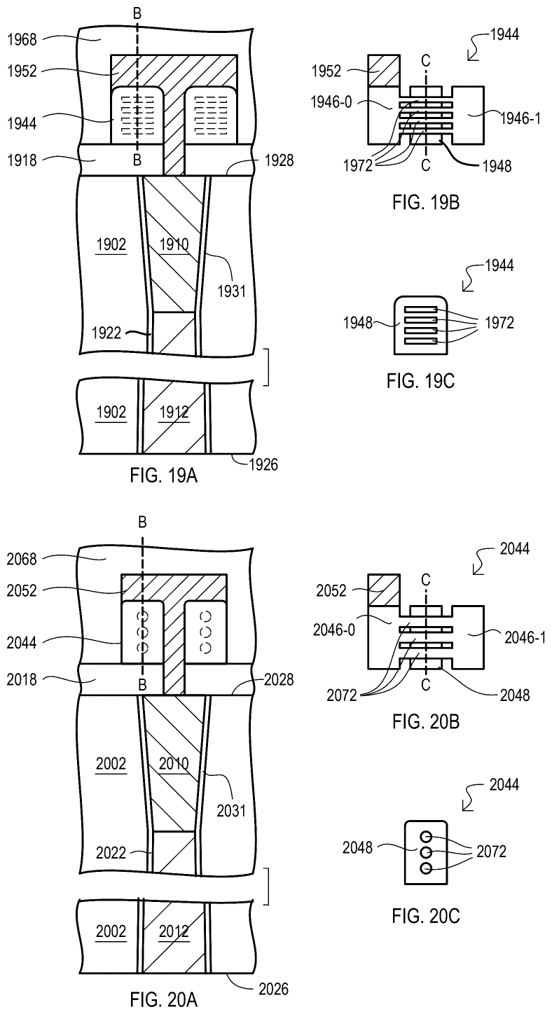

FIGS. 19A to 19C are cross sectional views showing connections between an IGFET source or drain (S/D) to a through via according to an embodiment. FIG. 19A is a cross sectional view showing IGFETs 1944 formed on a front side insulator 1918 above a second (e.g., top) surface 1928 of a substrate 1902. A via contact 1952 can be formed that contacts a top and side surface of an IGFET 1944. While FIG. 19A shows such a contact to S/Ds of adjacent IGFETs, alternate embodiments can include a contact with one IGFET. Conversely, a via contact 1952 can make contact with more than two S/Ds. A via contact 1952 can make contact with a buried conductive line 1910. While FIG. 19A shows a buried conductive line 1910 having a top coplanar with a second surface 1928, alternate embodiments can include buried conductive lines having portions that extend above a second surface 1928. Buried conductive line 1910 can be contact with through via 1912, which can extend between first and second sides of a substrate 1902. A top insulator 1968 can be formed over via contact 1952. Buried conductive line 1910 and through via 1912 can be insulated from a substrate by line insulator 1931 and via insulator 1922, respectively.

FIG. 19B is a side cross sectional view of an IGFET 1944 along line B-B of FIG. 19A. IGFET 1944 can include a first S/D 1946-0, a second S/D 1946-1, channels 1972, and surrounding gate 1948. First S/D 1946 can be in contact with via contact 1952. In some embodiments, such a via contact 1952 can provide a power supply voltage. Channels 1972 can be flat, rectangular structures (e.g., nanosheets) formed between first and second S/Ds (1946-0/1). A surrounding gate 1948 can surround channels 1972 and be separated therefrom by a gate insulator (not shown).

FIG. 19C shows a side cross sectional view of an IGFET 1944 along line C-C of FIG. 19B. The view shows a surrounding gate 1948 around channels 1972 (which are separated by a gate insulator).

FIGS. 20A to 20C are cross sectional views showing connections between an IGFET S/D to a through via according to another embodiment. FIGS. 20A to 20C show items like those of FIGS. 19A to 19C, and such like items are referred to by the same reference character but with the leading digits being “20” instead of “19”. FIGS. 20A to 20C can differ from FIGS. 19A to 19C in that an IGFET 2044 can include substantially cylindrical channels 2072 (e.g., nanotubes).

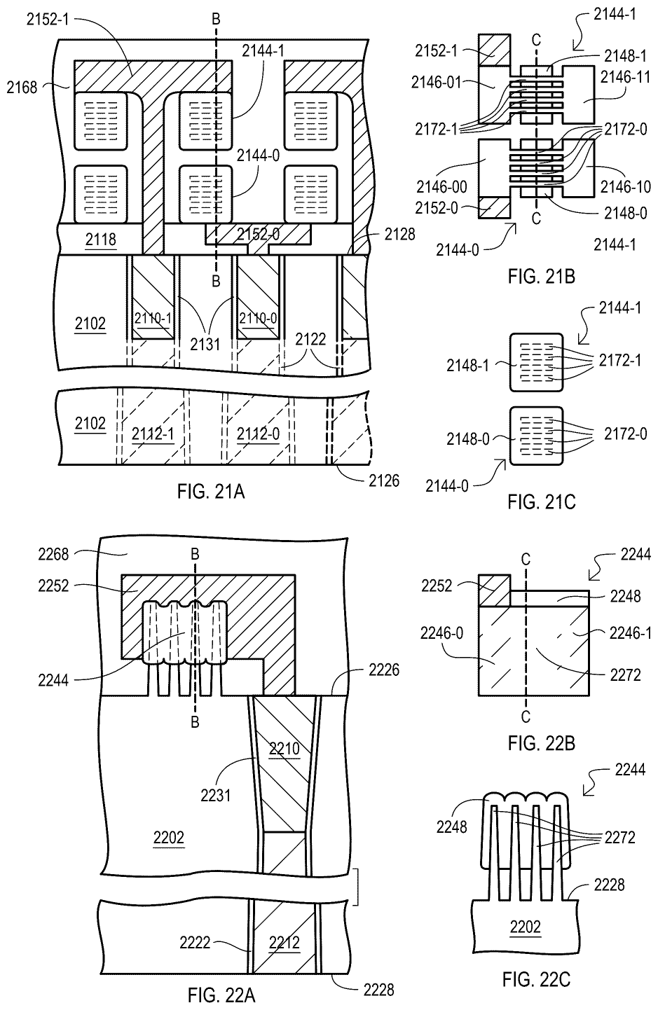

FIGS. 21A to 21C are cross sectional views showing connections between an IGFET S/D to a through via according to another embodiment. FIGS. 21A to 21C show items like those of FIGS. 19A to 19C, and such like items are referred to by the same reference character but with the leading digits being “21” instead of “19”. FIGS. 21A to 20C can differ from FIGS. 19A to 19C in that stacked pairs of IGFETs 2144-0/1 are formed over a second surface 2128. In some embodiments, each IGFET of a stacked pair can be of a different conductivity type.

Referring to FIG. 21A, a first via contact 2152-0 can make contact with an S/D of a first (e.g., bottom) IGFET 2144-0. A second via contact 2152-1 can make contact with an S/D of a second (e.g., top) IGFET 2144-1. First via contact 2152-0 can be in contact with a first buried conductive line 2110-0, which can be in contact with a first through via 2112-0. Second via contact 2152-1 can be in contact with a second buried conductive line 2110-1, which can be in contact with a second through via 2112-1. In some embodiments, first and second through vias can receive different power supply voltages.

FIG. 21B is a side cross sectional view taken along line B-B of FIG. 21A. FIG. 21B shows a stacked pair of IGFETs 2144-0/1, each with a first S/D 2146-00/01, second S/D 2146-10/11, channels 2172-0/1, and surrounding gate 2148-0/1. A first S/D 2146-00 of (bottom) IGFET 2144-0 can be contact with a first via contact 2152-0. A first S/D 2146-01 of (top) IGFET 2144-1 can be contact with a second via contact 2152-1. FIG. 21C is a side cross sectional view taken along line C-C of FIG. 21B.

FIGS. 22A to 22C are cross sectional views showing connections between an IGFET S/D to a through via according to another embodiment. FIGS. 22A to 22C show items like those of FIGS. 19A to 19C, and such like items are referred to by the same reference character but with the leading digits being “22” instead of “19”. FIGS. 22A to 22C can differ from FIGS. 19A to 19C in that an IGFET 2244 can include channels 2272 that extend upward from a second surface 2228 (e.g., fins).

According to some embodiments, an IC device can include separate power supply routings from a front side to a back side. Such an arrangement can enable circuits of as a same IC device to receive power supplies that are different in any suitable manner, including but not limited to, quality, capacity, or magnitude.

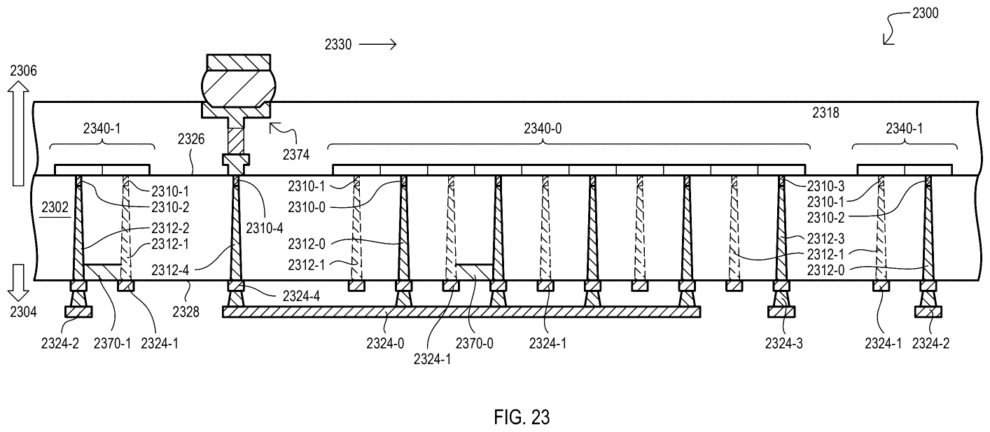

FIG. 23 is a side cross sectional view of an IC device 2300 according to another embodiment. In some embodiments, an IC device 2300 can be one implementation any shown in FIGS. 1 to 3. An IC device 2300 can include a substrate 2302, a first side 2304 and second side 2306. First circuits 2340-0 and second circuits 2340-1 can be formed at a second side 2306. First and second circuits 2340-0/1 can include IGFETs as described herein, or equivalents, including rows of IGFETs.

An IC device 2300 can include buried conductive lines formed in a top surface 2326, including first buried conductive lines 2310-0, second buried conductive lines 2310-1, and third buried conductive lines 2310-2. In addition, a first buried conductive structure 2310-3 and second buried conductive structure 2310-4 can be formed in a top surface 2326. First, second and third buried conductive lines 2310-0 to -2 can be parallel to one another in a second direction, and extend in a first direction (e.g., into the plane of FIG. 23). In some embodiments, first and second buried conductive structures 2310-3/4 can be formed in the same manner as buried conductive lines 2310-0/1/2. In some embodiments, conductive lines/structures 2310-0 to -4 can be insulated from a substrate 2302 by a line insulator.

An IC device 2300 can include first through vias 2312-0, second through vias 2312-1, third through vias 2312-2, fourth through vias 2312-3 and fifth through vias 2312-4. Through vias 2312-0 to -4 can extend between first and second sides (2304, 2306) through substrate 2302. In some embodiments, through vias 2312-0 to -4 can be insulated from a substrate 2302 by a via insulator.

A first power supply network can be formed by first buried conductive lines 2310-0 conductively connected to first through vias 2312-0, which can be conductively connected to a back side routing first portion 2324-0. Such a first supply network 2310-0/2312-0/2324-0 can include back side routing first portion 2324-0 connected to a first device terminal. A second power supply network can be formed by second buried conductive lines 2310-1 conductively connected to second through vias 2312-1, which can be conductively connected to a backside routing second portion 2324-1. Such a second power supply network 2310-1/2312-1/2324-1 can include back side routing second portion 2324-1 connected to a second device terminal. A third power supply network can be formed by third buried conductive lines 2310-2 conductively connected to third through vias 2312-2, which can be conductively connected to a backside routing third portion 2324-2. Such a third power supply network 2312-1/2312-2/2324-2 can include back side routing second portion 2324-2 connected to a third device terminal.

In some embodiments, such power supply networks can be separate from one another. That is, with respect to IC device 2300 a static conductive path does not exist between such power supply networks. In some embodiments, a first power supply network 2301-0/2312-0/2324-0 can provide a high power supply voltage (e.g., VDD), a second power supply network 2301-1/2312-1/2324-1 can provide a lower power supply voltage (e.g., VSS), and a third power supply network 2301-2/2312-2/2324-2 can provide a separate high power supply voltage, which may or may not be the same as the first higher power supply voltage (e.g., VDD or VPP>VDD). In some embodiments, second circuits 2340-1 can include input buffer circuits and a third power supply network 2301-2/2312-2/2324-2 can provide a power supply voltage that has less noise or other variation with respect to a power supply provided by a first power supply network 2301-0/2312-0/2324-0. For example, a power supply voltage or a reference voltage used in a comparator circuit to set input signal value levels.

First buried conductive structure 2310-3, fourth through via 2312-3, and back side routing fourth portion 2324-3 can provide an independent signal path that does not provide a power supply voltage. A back side routing fourth portion 2324-3 can be connected to a fourth device terminal. An independent signal path 2310-3/2312-3/2324-3 can provide an output signal from and/or an input signal to IC device 2300. Such signals can include but are not limited to a digital output signal, an analog output signal, a digital input signal (e.g., logic, clock), or an analog input signal (e.g., reference voltage, sample voltage).

Second buried conductive structure 2310-4, fifth through via 2312-4, and back side routing fifth portion 2324-4 can provide a through signal path that provides a conductive path through a substrate 2302 to another device, via a second side connection 2374. That is, second side connection 2374 can have a conductive connection to another device formed over second side 2306. While FIG. 23 shows a second side connection 2374 connected to back side routing first portion 2324-0, second side connection 2374 could receive a signal from/to any other suitable routing portion, including but not limited to, power supply voltages utilized by IC device 2300, power supply voltages independent of IC device 2300 (e.g., power supplied that “pass through” IC device 2300 to another device, I/O signals utilized by IC device 2300 and/or I/O signals independent of IC device 2300. Second buried conductive structure 2310-4 may be wider than other buried conductive structures 2310-0/1/2 in order to reduce resistance when passing through to another device. It is understood that multiple fifth through vias 2312-4 may also be placed in a line along second buried conductive structure 2310-4 to further reduce resistance.

Referring still to FIG. 23, an IC device 2300 can include first and second electrostatic discharge protection (ESD) circuits 2370-0 and 2370-1 formed at a first side 2304. In some embodiments, all or a portion of ESD circuits 2370-0/1 can be formed in a first surface 2328. A first ESD circuit 2370-0 can be electrically connected between a first power supply network 2310-0/2312-0/2324-0 and a second power supply network 2310-1/2312-1/2324-1. A second ESD circuit 2370-1 can be electrically connected between a third power supply network 2310-2/2312-2/2324-2 and a second power supply network 2310-1/2312-1/2324-1. In some embodiments, such an arrangement can place first and second ESD circuits 2370-0/1 between different power terminals of a device.

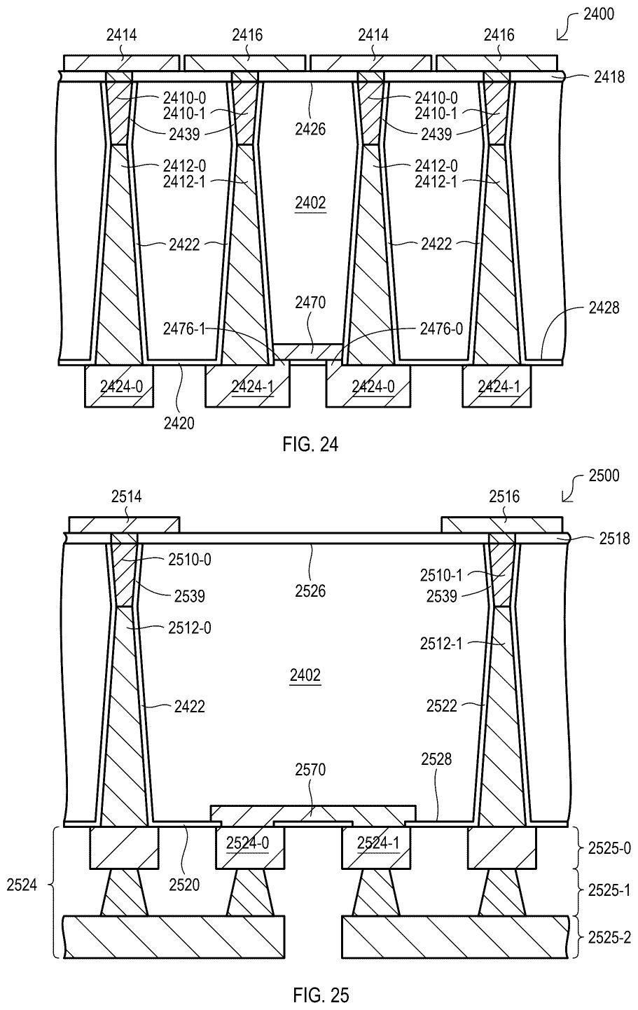

FIG. 24 is a side cross sectional view of an IC device 2400 according to another embodiment. In some embodiments, an IC device 2400 can be one implementation of any of those shown in FIG. 1, 2, 3 or 23. An IC device 2400 can include first and second buried conductive lines 2410-0/1 formed in a front surface 2426 of a substrate 2402. First and second rows of IGFETs 2414/16 can be formed over a front surface 2426 on a front side insulator 2418, with first IGFET rows 2414 being connected to first buried conductive lines 2410-0 and second IGFET rows 2416 being connected to second buried conductive lines 2410-1. First buried conductive lines 2410-0 can be in contact with first through vias 2412-0 that can be formed within substrate 2402 between a front side 2426 and a back side 2428. First through vias 2412-0 can be connected to back side routing first portions 2424-0, which can be formed over a back surface 2428 on a back side insulator 2420. Similarly, second through vias 2412-1 can be connected to back side routing second portions 2424-1, which can be formed over a back surface 2428 on back side insulator 2420. First and second buried conductive lines 2410-0/1 can be insulated from a substrate 2402 by a line insulator 2439. First and second vias 2412-0/1 can be insulated from a substrate 2402 by a via insulator 2422.

In some embodiments, an IC device 2400 can include a first power supply network 2410-0/2412-0/2424-0 and a second power supply network 2410-1/2412-1/2424-1, in the same or equivalent manner as FIG. 23.

An ESD circuit 2470 can be formed, at least in part, in a substrate 2402 at a back surface 2428. An ESD circuit 2470 can have a first conductive connection 2476-0 to a first through via 2412-0 by a same part of a back side routing first portion 2424-0. An ESD circuit 2470 can have a second conductive connection 2476-1 to a second through via 2412-1 by a same part of a back side routing second portion 2424-1. In some embodiments, an IC device 2400 can include an intermediate layer where a back side routing contacts a back surface 2428 (e.g., silicide).

FIG. 25 is a side cross sectional view of an IC device 2500 according to another embodiment. In some embodiments, an IC device 2500 can be one implementation of that shown in any of FIG. 1, 2, 3 or 23. An IC device 2500 can include items like those of FIG. 24, and such like items are referred to by the same reference character but with the leading digits being “25” instead of “24”.

FIG. 25 can differ from that of FIG. 24 in that a back side routing 2524 can include a first backside layer 2525-0, second back side layer 2525-1, and third back side layer 2525-2. Conductive connections between ESD circuit 2570 and first and second through vias 2512-0/1 can be completed through two or more layers of back side routing 2524. In this way, ESD triggering events may have a current path between backside routing portions 2524-0 and 2524-1 and damage to electrical connections between the backside and frontside of IC device 2500 may be minimized. Other advantages can include resistive control between backside routing portions 2524-0 and 2524-1 along the ESD discharge path through ESD circuit 2570 to optimize the ESD trigger voltage.

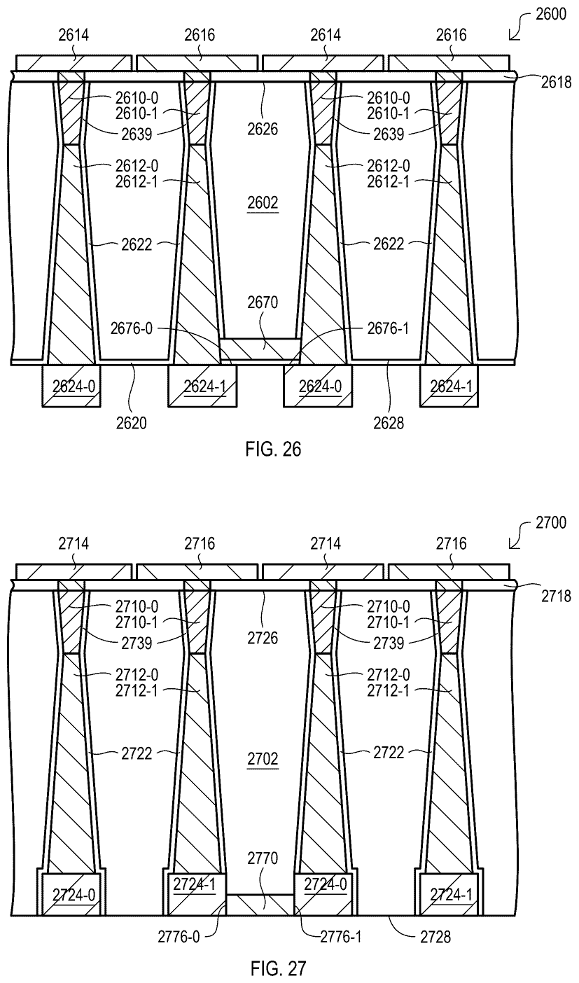

FIG. 26 is a side cross sectional view of an IC device 2600 according to another embodiment. In some embodiments, an IC device 2600 can be one implementation of that shown in any of FIG. 1, 2, 3 or 23. An IC device 2600 can include items like those of FIG. 24, and such like items are referred to by the same reference character but with the leading digits being “26” instead of “24”.

FIG. 26 can differ from that of FIG. 24 in that connections 2676-0/1 between ESD circuit 2670 can be made directly to first and second through vias 2612-0/1. Such connections 2676-0/1 may or may not have a conductive connection to a back side routing 2624-0/1. By reducing the distance from the ESD circuit 2670 to through vias 2612-0/1, and an ESD event may trigger ESD circuit 2670 and reduce the probability that the ESD even damages the front side IGFETs 2614/2616.

FIG. 27 is a side cross sectional view of an IC device 2700 according to another embodiment. In some embodiments, an IC device 2700 can be one implementation of that shown in any of FIG. 1, 2, 3 or 23. An IC device 2700 can include items like those of FIG. 24, and such like items are referred to by the same reference character but with the leading digits being “27” instead of “24”.

FIG. 27 can differ from that of FIG. 24 in that back side routing first and second portions 2724-0/1 can be formed in a substrate 2702, and connections 2776-0/1 between ESD circuit 2770 can be made directly to such back side routing portions 2724-0/1. An ESD event may trigger ESD circuit 2770 and reduce the probability that the ESD even damages the front side IGFETs 26714/26716 in a similar manner as discussed above.

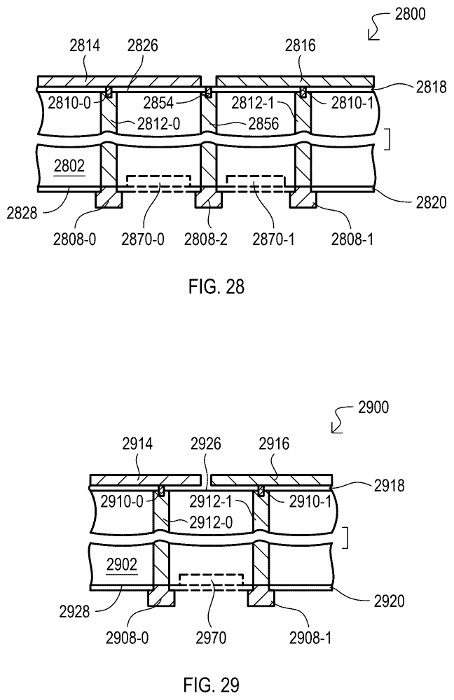

FIG. 28 is a side cross sectional view of an IC device 2800 according to another embodiment. In some embodiments, an IC device 2800 can be one implementation of any of those shown in FIG. 1, 2, 3 or 23. An IC device 2800 can include a high power supply buried conductive line 2810-0, a low power supply buried conductive line 2810-1, and an I/O conductive structure 2854 formed in a front surface 2826 of a substrate 2802. A row of p-type IGFETs 2814 can be formed over a front surface 2818 of a substrate 2802 on a front side insulator 2818, and can include one or more transistors having a conductive connection to high power supply buried conductive line 2810-0. A row of n-type IGFETs 2816 can be formed over a front surface 2826 of a substrate 2802 on a front side insulator 2818, and can include one or more transistors having a conductive connection to low power supply buried conductive line 2810-1. I/O buried conductive structure 2854 can have a conductive connection to one or more transistors in p-type IGFET row 2814 and/or n-type IGFET row 2816.

A high power supply voltage (e.g., VDD) can be provided to a high power supply terminal 2808-0 formed over a back surface 2820 of substrate 2802. A high power supply voltage can be provided from high power supply terminal 2808-0 to high power supply buried conductive line 2810-0 with through via 2812-0 which can extend between front and back surfaces 2828/2820 within substrate 2802.

A low power supply voltage (e.g., VSS) can be provided to a low power supply terminal 2808-1 formed over a back surface 2828 of substrate 2802. A low power supply voltage can be provided from low power supply terminal 2808-1 to low power supply buried conductive line 2810-1 with through via 2812-1 which can extend between front and back surfaces 2828/2826 within substrate 2802.

An I/O via 2856 can provide a conductive connection between I/O buried conductive structure 2854 and an I/O terminal 2808-2 formed over a back surface 2828. A signal path for an input or output signal can be provided by I/O conductive structure 2854, I/O via 2856 and I/O terminal 2808-2.

Referring still to FIG. 28, an IC device 2800 can include a first ESD circuit portion 2870-0 and second ESD circuit portion 2870-1. First ESD circuit portion 2870-0 can have a conductive connection between a high power supply terminal 2808-0 and an I/O terminal 2808-2. Second ESD circuit portion 2870-1 can have a conductive connection between a low power supply terminal 2808-1 and an I/O terminal 27808-2. Such conductive connections between ESD circuit portions 2870-0/1 and terminals 2808-0/1/2 can be direct, or indirect, and can take the form of any of those described herein, or equivalents.

FIG. 29 is a side cross sectional view of an IC device 2900 according to another embodiment. In some embodiments, an IC device 2900 can be one implementation of any of those shown in FIG. 1, 2, 3 or 23. An IC device 2900 can include items like those of FIG. 28, and such like items are referred to by the same reference character but with the leading digits being “29” instead of “28”. IC device 2900 can differ from that of FIG. 28 in that an ESD circuit 2970 can have conductive connections between a high power supply terminal 2908-0 and a low power supply terminal 2908-1. Such conductive connections between ESD circuit 2970 and terminals 2908-0/1 can be direct, or indirect, and can take the form of any of those described herein, or equivalents.

Embodiments can include IC devices having circuits formed with rows of IGFETs formed on and/or over a front surface of a substrate, and with ESD circuits formed on and/or over a back surface of a substrate. Such ESD circuits can take any suitable form and include any suitable circuit elements.

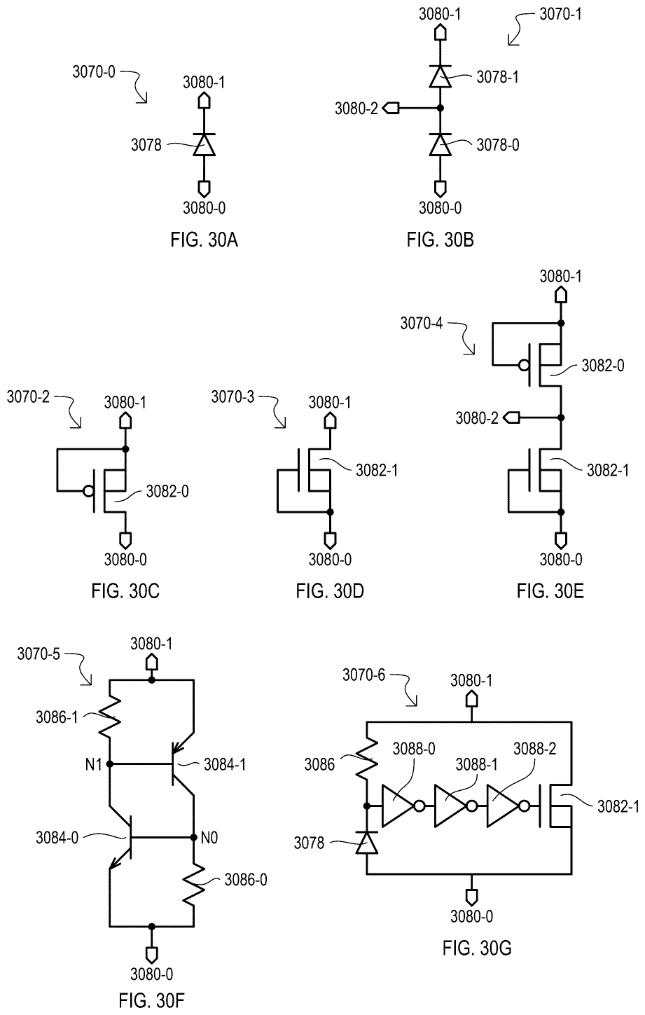

FIGS. 30A to 30G are schematic diagrams of ESD circuits that can be included in embodiments. FIG. 30A shows an ESD circuit 3070-0 that can include a diode 3078 having an anode connected to a first terminal 3080-0 and a cathode connected to a second terminal 3080-1. FIG. 30B shows an ESD circuit 3070-1 according to another embodiment. ESD circuit 3070-1 can include a first diode 3078-0 and second diode 3078-1 connected in series. A first diode 3078-0 can have an anode connected to a first terminal 3080-0. A second diode 3078-1 can have a cathode connected to a second terminal 3080-1. A cathode of first diode 3078-0 and anode of second diode 3078-1 can be connected to a third terminal 3080-2. In some embodiments, any of diodes 3078, 3078-0/1 can be formed all, or in part, within and/or over a back surface of a substrate.

FIG. 30C shows an ESD circuit 3070-2 according to a further embodiment. ESD circuit 3070-2 can include a p-type IGFET in a “diode” configuration having a drain connected to a first terminal 3080-0 and a gate, source (and body if present) connected to a second terminal 3080-1. FIG. 30D shows an ESD circuit 3070-3 according to another embodiment. ESD circuit 3070-3 can include an n-type IGFET in a diode configuration between first and second terminals 3080-0/1. FIG. 30E shows an ESD circuit 3070-4 that can include an n-type IGFET 3082-1 and p-type IGFET 3082-0, both in diode configuration. A source and gate of n-type IGFET 3082-1 can be connected to a first terminal 3080-0. A source and gate of p-type IGFET 3082-0 can be connected to a second terminal 3080-1. Drains of the IGFETs 3082-0/1 can be connected to a third terminal 3080-2. In some embodiments, any of IGFETs 3082-0/1 can be formed all, or in part, within and/or over a back surface of a substrate.

FIG. 30F shows an ESD circuit 3070-5 according to a further embodiment. An ESD circuit 3070-5 can be a silicon-controlled-rectifier (SCR) type circuit. In the embodiment shown, ESD circuit 3070-5 can include an npn bipolar transistor 3084-0, a pnp bipolar transistor 3084-1, a first resistor 3086-0 and a second resistor 3086-1. An npn bipolar transistor 3084-0 can have an emitter connected to a first terminal 3080-0, a base connected to a node NO, and a collector connected to a node N1. A first resistor 3086-0 can be connected between a first terminal 3080-0 and node NO. A pnp bipolar transistor 3084-1 can have an emitter connected to a second terminal 3080-1, a base connected to a node N1, and a collector connected to node NO. A second resistor 3086-1 can be connected between node N1 and second terminal 3080-1. In some embodiments, any of the circuit elements of ESD circuit 3070 can be formed all, or in part, within and/or over a back surface of a substrate.

FIG. 30G shows a protection circuit 3070-6 that can be included in embodiments. A protection circuit 3070-6 can include diode 3078, resistor 3086, a first inverter 3088-0, second inverter 3088-1, third inverter 3088-2, and an n-type IGFET 3082. A diode 3078 can have an anode connected to a first terminal and a cathode connected to node N2. Resistor 3086 can be connected between node N2 and a second terminal 3080-1. Inverters 3088-0/1/2 can be arranged in series between node N2 and a gate of IGFET 3082-1. IGFET 3082-1 can have a source (and if included body) connected to first terminal 3080-0 and a drain connected to second terminal 3080-1.

As but one example, ESD circuits 3070-1, 3070-4 may have terminals 3080-0, 3080-1, and 3080-2 electrically connected to a first power supply voltage (e.g. VSS), a second power supply voltage (e.g. VDD), and an I/O terminal, respectively.

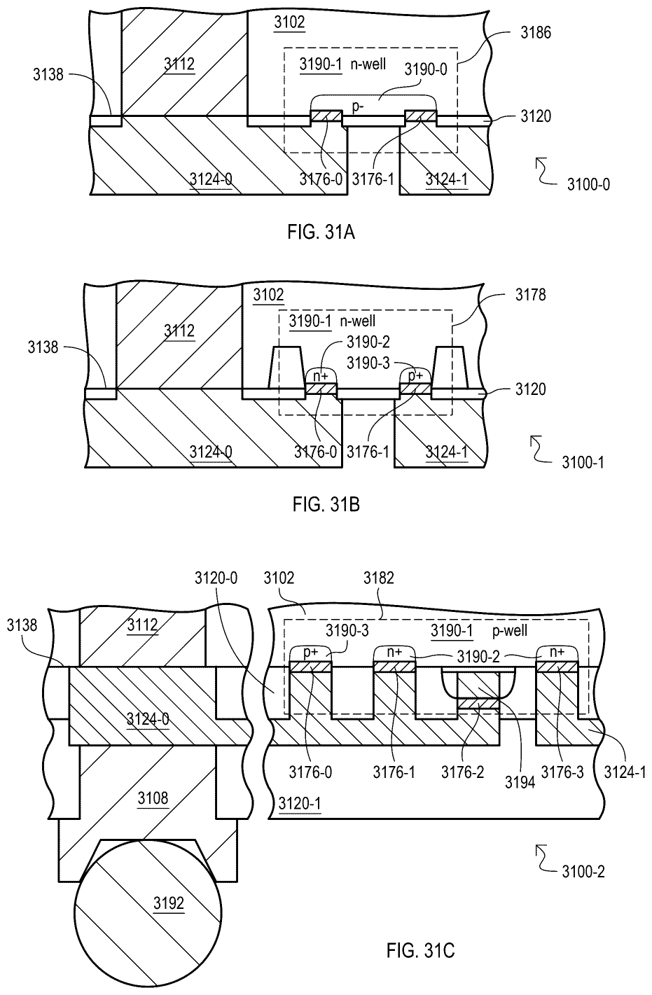

FIGS. 31A to 31C are side cross sectional views of back side circuit elements according to embodiments. Such circuit elements can be formed with a back side of a substrate that can provide conductive connections to a through via or equivalent structure that provides a conductive connection to circuits at or over a front side of a substrate.

FIG. 31A is a side cross sectional view of an IC device 3100-0 according to an embodiment. An IC device 3100-0 can include a substrate 3102, a through via 3112, a back side insulator 3120, and back side routing portions 3124-0/1. A resistor 3186 can be formed below a back surface 3138 in a substrate 3102. In the embodiment shown, a resistor 3186 include a lightly doped region (e.g., p−) 3190-0 formed on an oppositely doped region (e.g., n-well) 3190-1. A resistor 3186 can have a first connection 3176-0 to a back side routing first portion 3124-0, which can be conductively connected to a through via 3112. A resistor 3186 can have a second connection 3176-1 to a back side routing second portion 3124-1. In the embodiment shown, connections 3176-0/1 can extend through a back side insulator 3120.

FIG. 31B is a side cross sectional view of an IC device 3100-1 according to another embodiment. An IC device 3100-1 can include items like those of FIG. 31A, and such like items are referred to by the same reference characters. IC device 3100-1 can differ from that of FIG. 31A in that a diode 3178 can be formed below a back surface 3138 in a substrate 3102. In the embodiment shown, a diode 3178 can include a region of a first doping type 3190-1/2 (e.g., n+ in n-well) and a region of a second doping type 3190-3 (e.g., p+).

FIG. 31C is a side cross sectional view of an IC device 3100-2 according to another embodiment. An IC device 3100-2 can include items like those of FIG. 31A, and such like items are referred to by the same reference characters. IC device 3100-2 can differ from that of FIG. 31A in that an IGFET 3182 can be formed with a back surface 3138 in a substrate 3102. In the embodiment shown, an IGFET 3182 can include a first and second S/Ds 3190-2, a gate structure 3194 and a body contact 3190-3. An IGFET 3182 can have a body connection 3176-0, first S/D connection 3176-1 and gate connection 3176-2 to a back side routing first portion 3124-0. IGFET 3182 can have a second S/D connection 3176-3 to a back side routing second portion 3124-1. Connections 3176-0/1/2 to IGFET 3182 can be made through a first back side insulator 3120-0. A second back side insulator 3120-1 can be formed over back side routing 3124-0/1.

Referring still to FIG. 31C, an IC device 3100-2 can include a terminal 3108 with a conductive connection to back side routing first portion 3124-0. In the embodiment shown, terminal 3108 can be a grid array type terminal (e.g., ball grid array, microball array), which can be configured to receive a conductive ball 3192. However, such a particular connection should not be construed as limiting. Embodiments can include any suitable terminals for making an electrical connection to an IC device.

Embodiments can include IC devices having circuits at first and second sides of a substrate, where such circuits can be conductively connected with one another by way of through vias within the substrate.

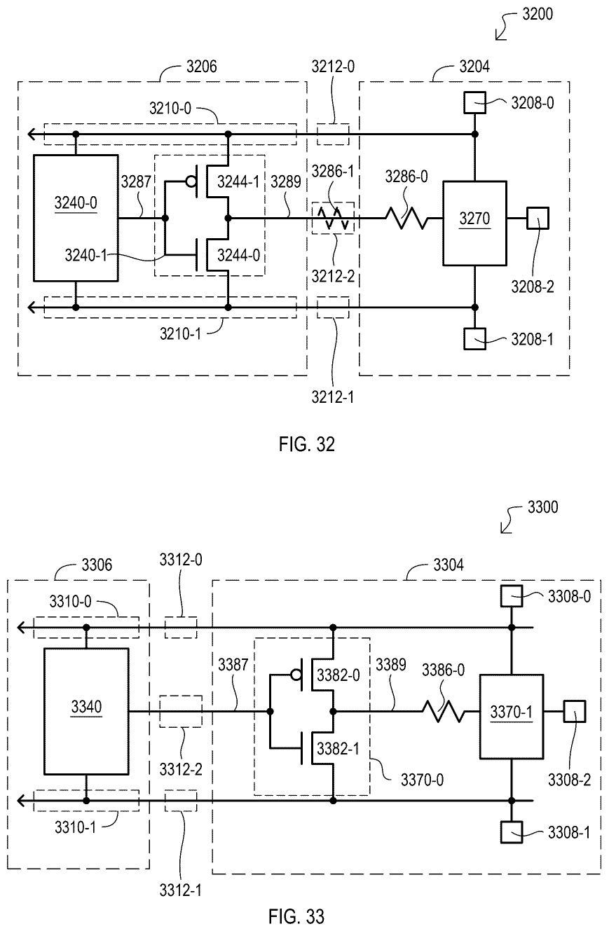

FIG. 32 is a block schematic diagram of an IC device 3200 according to an embodiment. An IC device 3200 can include a first side 3204 of a substrate and a second side of a substrate 3206. Logic circuits 3240-0 and an output driver 3240-1 can be formed at a second (front) side 3206. Logic circuits 3240-0 can be connected to a first buried conductive line 3210-0 that can carry a high power supply voltage, and a second buried conductive line 3210-1 that can carry a low power supply voltage. Logic circuits 3240-0 can provide an output signal to an input node 3287. Output driver 3240-1 can include an n-type IGFET 3244-0 and p-type IGFET 3244-1. An n-type IGFET 3244-0 can have a gate connected to input node 3287, a source connected to second buried conductive line 3210-1, and a drain connected to an output node 3289. A p-type IGFET 3244-1 can have with a gate connected to input node 3287, a source connected to first buried conductive line 3210-0, and a drain connected to an output node 3289. In some embodiments, Logic circuits 3240-0 and/or output driver 3240-1 can be formed from rows of IGFETs with surrounding gates, with such rows of IGFETs having conductive connections to first and second buried conductive lines 3210-0/1 as described herein and equivalents.

An ESD circuit 3270, first power supply terminal 3208-0, second power supply terminal 3208-1, and an output terminal 3208-2 can be formed at a first (back) side 3204. A high power supply voltage can be received at a first power supply terminal 3208-0 and provided to first buried conductive line 3210-0 with a first through via 3212-0. A low power supply voltage can be received at a second power supply terminal 3208-1 and provided to second buried conductive line 3210-1 with a second through via 3212-0. An output signal driven on output node 3289 by output driver 3240-1 can be provided to an ESD circuit 3270 by an output through via 3212-2. First, second and output through vias 3212-0/1/2 can take the form of any of those described herein and equivalents. In some embodiments, an output node 3289 can be a third buried conductive line or structure.

In some embodiments, a resistor can be present between output node 3289 and ESD circuit 3270. In some embodiments, an output through via 3212-2 can include a resistor 3286-1. As a result, a resistance of output through via 3212-2 can be greater than that of first and second through vias 3212-0/1. In addition or alternatively, a resistor 3286-0 can be formed at the first side 3204. ESD circuit 3270 can be conductively connected between first power supply terminal 3208-0 and second power supply terminal 3208-1, and provide an output signal path from output node 3289 to output terminal 3208-2. In some embodiments, a resistor 3286-0 can be formed in a back surface as described herein, or an equivalent. In some embodiments, all or a portion of ESD circuit 3470 can take the form of those described herein, or an equivalent. It is understood that IGFETs 3244-0/1 may be IGFETs having a plurality of channels formed between respective source/drains and have contiguous gate structures surrounding respective channels.

FIG. 33 is a block schematic diagram of an IC device 3300 according to another embodiment. An IC device 3300 can include items like those shown in FIG. 32, and such like items are referred to by the same reference character but with the leading digits being “33” instead of “32”. IC device 3300 can differ from that of FIG. 33 in that an output driver circuit 3370-0 can be formed at a first side 3304. In some embodiments, p-type IGFET 3382-0 and n-type IGFET 3382-1 of output driver 3370 can be formed with a back surface as described herein, or an equivalent.

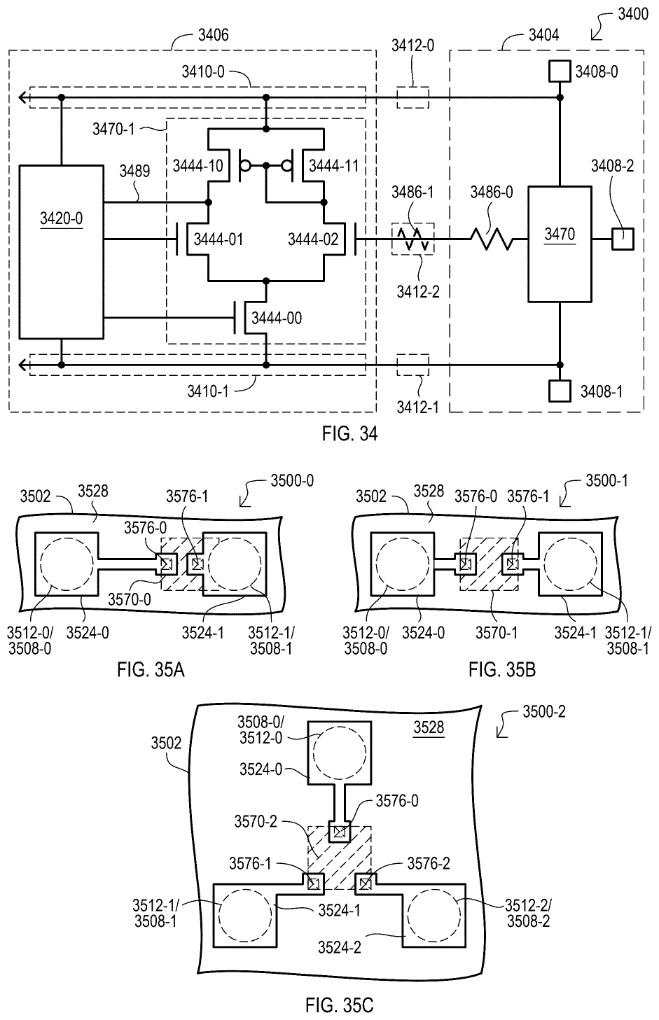

FIG. 34 is a block schematic diagram of an IC device 3400 according to another embodiment. An IC device 3400 can include items like those shown in FIG. 32, and such like items are referred to by the same reference character but with the leading digits being “34” instead of “32”. IC device 3400 can differ from that of FIG. 32 in that an input buffer circuit 3470-1 can be formed at a second side 3406. An input buffer 3470-1 can take any suitable form, and in the embodiment shown can include p-type IGFETs 3444-10/11 and n-type IGFETs 3444-00/01/02. P-type IGFETs 3444-10/11 can be connected in a current mirror configuration having sources commonly connected to a first buried conductive line 3410-0, and a common connection between the gates of both p-type IGFETs 3444-10/11 and drain of p-type IGFET 3444-11. N-type IGFET 3244-00 can have a source connected to second buried conductive line 3410-1, a gate connected to receive an enable signal or a reference voltage, and a drain connected to the sources of n-type IGFETs 3444-01/02. N-type IGFET 3444-02 can have a gate that receives an input signal from input through via 3412-2 and drain connected to the gate-drain of p-type IGFET 3444-11. N-type IGFET 3444-01 can have a gate that receives a reference voltage from circuits 3420-0, and a drain connected to a drain of p-type IGFET 3444-10, which can also be an output node 3489 of input buffer.

Input buffer circuit 3470-1 can receive an input signal from an input through via 3412-2. Input through via 3412-2 can receive the input signal from input terminal 3408-2. ESD circuit 3470 can provide a signal path between input terminal 3408-2 and input through via 3412-2. In some embodiments, a resistor (3486-0 and/or 3486-1) can be included, as described for FIG. 32.

In some embodiments, logic circuits 3420-0 can include additional reference voltage generating circuits and/or can receive reference voltages for application to input buffer circuit 3470-1. In some embodiments, all or a portion of input buffer circuit 3470-1 can be formed from rows of IGFETs, as described herein, or equivalents. Logic circuits 3420-0 and input buffer circuit 3470-1 can be included in 2340-1 of FIG. 23 to reduce noise on voltages and signals.

According to embodiments, connections between ESD circuits can be connected to through vias and/or device terminals in any suitable fashion. Further, ESD circuits can include two terminal and three terminal ESD circuits.

FIGS. 35A to 35C are back views of an IC device showing connections to ESD circuits according to embodiments. FIG. 35A shows a first (e.g., back) side of an IC device 3500-0 according to an embodiment. An IC device 3500-0 can include a back side 3528 of a substrate 3502 that includes an ESD circuit 3570-0, back side routing first portion 3524-0 and back side routing second portion 3524-1. An ESD 3570-0 circuit can be formed in and/or on a back side surface 3528. An ESD circuit 3570-0 can be a two-terminal circuit, and in some embodiments can take the form of any of those shown herein and equivalents. A back side routing first portion 3524-0 can include a first contact 3576-0 to a first terminal of ESD circuit 3570-0, and can be in conductive contact with a first through via 3512-0 and/or a first terminal 3508-0. A back side routing second portion 3524-1 can include a second contact 3576-1 to a second terminal of ESD circuit 3570-0, and can be in conductive contact with a second through via 3512-1 and/or second terminal 3508-1. FIG. 35A shows an arrangement in which a first through via/first terminal 3512-0/3508-0 can be formed away from an ESD circuit 3570-0 by back side routing first portion 3524-0. In contrast, a second through via 3512-1 can be formed next to, and in some embodiments in direct contact with ESD circuit 3570. A second terminal 3508-1 can be formed over an ESD circuit 3570-0. In some embodiments, a first through via or first terminal 3512-0/3508-0 can carry a first power supply voltage and a second through via or second terminal 3512-1/3508-1 can carry a second power supply voltage.

FIG. 35B shows a first (e.g., back) side of an IC device 3500-1 according to an embodiment. An IC device 3500-1 can include items like those of FIG. 35A, and such like items are referred to by the same reference characters. FIG. 35B can differ from FIG. 35A in that both first and second vias 3512-0/1 and/or both first and second terminals 3508-0/1 can be located away from ESD circuit 3570-1, and can have contacts 3576-0/1 to ESD circuit 3570-1 through extension of back side routing first and second portions 3524-0/1. In some embodiments, a first through via/terminal 3512-0/3508-0 can carry a first power supply voltage and a second through via/terminal 3512-1/3508-1 can carry a second power supply voltage.

FIG. 35C shows a first (e.g., back) side of an IC device 3500-2 according to another embodiment. An IC device 3500-2 can include items like those of FIG. 35A, and such like items are referred to by the same reference characters. FIG. 35C can differ from FIG. 35A in that an ESD circuit 3570-2 can be a three terminal circuit. A third through via 3512-2 and/or third terminal 3508-2 can be connected to ESD circuit 3570-2 at a third contact 3576-2. In some embodiments, a first through via/terminal 3512-0/3508-0 can carry a first power supply voltage, a second through via/terminal 3512-1/3508-1 can carry a second power supply voltage, and a third through via/terminal 3512-2/3508-2 can carry an input and/or output signal.

Embodiments can include ESD circuits formed at a first side of a substrate connected to logic circuits formed at a second side of the substrate by through vias and buried conductive lines. Such embodiments can show the formation of active devices (e.g., IGFETs, BJTs) and a passive device (e.g., resistor) at a first (e.g., back) side of an IC device. However, embodiments anticipate various other circuits and circuit structures formed at such a first side. In some embodiments, such circuits can include other passive circuits elements including but not limited to capacitors and/or inductors.

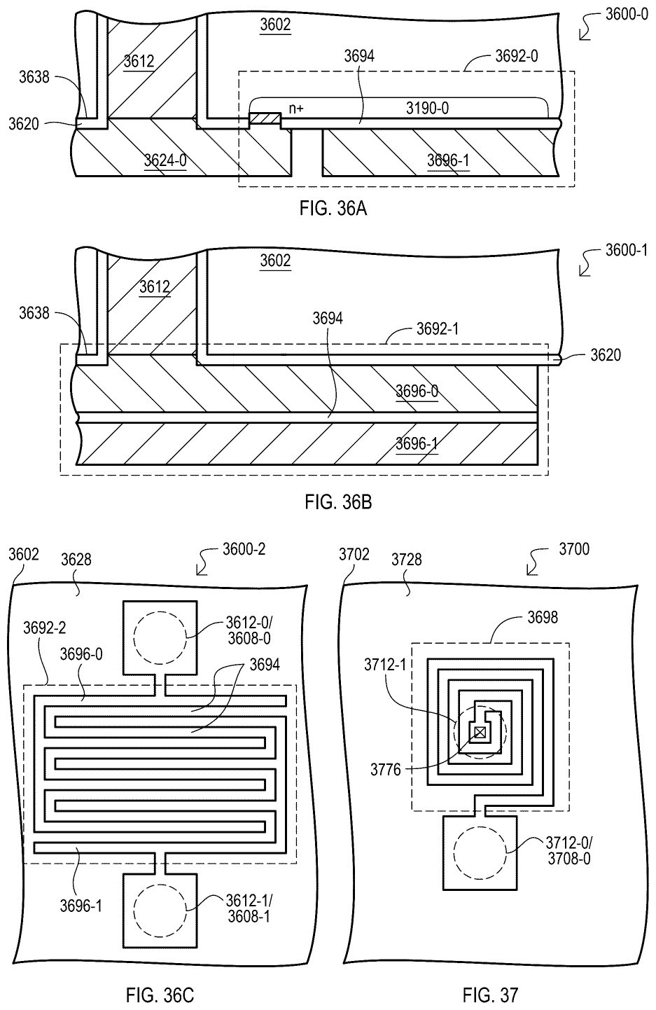

FIGS. 36A to 36C are diagrams showing capacitors that can be included in embodiments. FIG. 36A is a side cross sectional view of an IC device 3600-0 according to an embodiment. An IC device 3600-0 can include items like those shown in FIG. 31A, and such like items are referred to by the same reference character but with the leading digits being “36” instead of “31”. IC device 3600-0 can differ from that of FIG. 31A in that a capacitor 3692-0 can be formed with a substrate 3602. A capacitor 3692-0 can include a first plate 3190-0, which can be formed by a doping a portion of substrate to a relatively high conductivity (e.g., n+ in a p-type substrate). A first plate 3190-0 can separated from a second plate 3696-1 by a capacitor dielectric 3694. In some embodiments, a second plate 3696-1 can be formed with a back side routing layer. However, in other embodiments a second plate 3696-1 can be different from a back side routing layer (e.g., for a desired work function). A capacitor 3692-0 can be one version of a metal-oxide-semiconductor (MOS) type capacitor. The first plate 3190-0 can be electrically connected to routing layer 3624-0 (routing portion) which can be electrically connected to through via 3612 to provide an electrical connection to a front side of IC device 3600-0.

FIG. 36B is a side cross sectional view of an IC device 3600-1 according to an embodiment. An IC device 3600-1 can include items like those shown in FIG. 36A, and such like items are referred to by the same reference characters. IC device 3600-1 can differ from that of FIG. 36A in that a capacitor 3692-1 can be formed with a first plate 3696-0 formed over a substrate back surface 3638 (e.g., on back side insulator 3620). A capacitor dielectric 3694 can be formed on first capacitor plate 3696-0, and a second capacitor plate 3696-1 can be formed on capacitor dielectric 3694. First and/or second capacitor plates 3696-0/1 may or may not be formed with a back side routing layer. A capacitor 3692-1 can be one version of a metal-insulator-metal (MIM) type capacitor. The first plate 3696-0 can be electrically connected to through via 3612 to provide an electrical connection to a front side of IC device 3600-1.

FIG. 36C shows a first (e.g., back) side of an IC device 3600-2 according to another embodiment. An IC device 3600-2 can include items like those of FIG. 35A, and such like items are referred to by the same reference characters. FIG. 36C can differ from FIG. 35A in that a first via and/or terminal 3612-0/3608-0 can be conductively connected to a first capacitor plate 3696-0 and a second via and/or terminal 3612-1/3608-1 can be conductively connected to a second capacitor plate 3696-1. A capacitor dielectric 3694 can be formed between first and second capacitor plates 3696-0/1. First and/or second capacitor plates 3696-0/1 may or may not be formed with a back side routing layer. A capacitor 3692-2 can be one version of a metal-oxide-metal (MOM) type capacitor.

FIG. 37 shows a first (e.g., back) side of an IC device 3700 according to another embodiment. An IC device 3700 can include items like those of FIG. 36C, and such like items are referred to by the same reference characters but with the leading digits being “37” instead of “36”. FIG. 37 can differ from FIG. 36C in that a first via and/or terminal 3712-0/3708-0 can be conductively connected to a first terminal of an inductor 3698. A second terminal 3776 of inductor 3698 can be connected to a through via 3712-1 formed in a substrate 3702.

Embodiments can include IC devices having back side routing that can connect power supply voltages to circuits on a front side, using through vias, as well to circuits on a back side, such as ESD circuits.

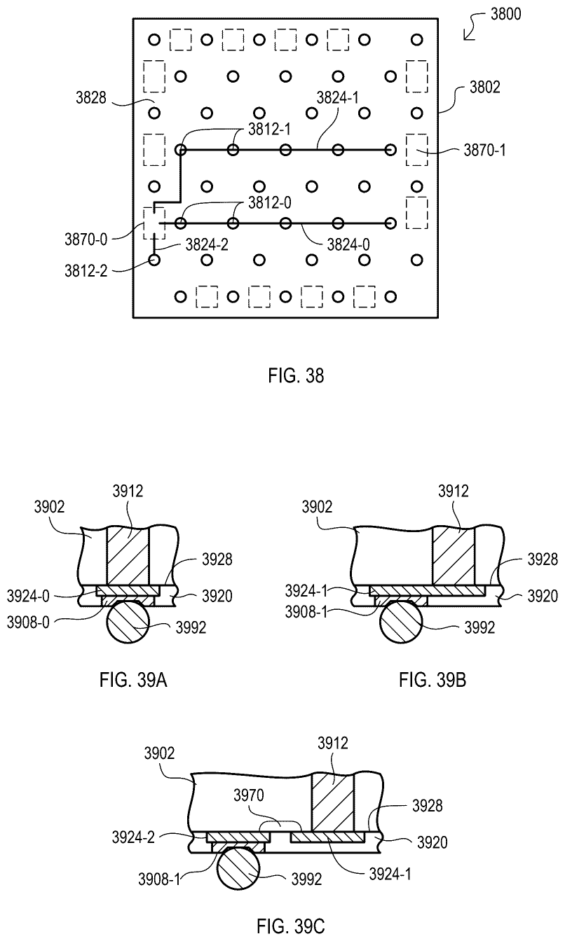

FIG. 38 shows a back side view of an IC device 3800 according to an embodiment. An IC device 3800 can include a back side routing first portion 3824-0, a back side routing second portion 3824-1, a back side routing third portion 3824-2, first through vias 3812-0, second through vias 3812-1, I/O through via 3812-2, and back side circuits 3870-0 and 3870-1. A back side routing first portion 3824-0 can be formed over a back surface 3828 and can have a conductive connection with first through vias 3812-0, and can connect to first back side circuit 3870-0. A back side routing second portion 3824-1 can be formed over a back surface 3828 and can have a conductive connection with second through vias 3812-1, and can connect to first back side circuit 3870-0. A back side routing third portion 3824-2 can be formed over a back surface 3828 can make direct conductive contact with I/O through via 3812-2, and connect to first back side circuit 3870-0.

In some embodiments, a back side routing first portion 3824-0 can receive a first power supply voltage and a back side routing second portion 3824-1 can receive a second power supply voltage. Such first and second power supply voltages can be received at terminals (not shown) of IC device 3800. A back side routing third portion 3824-2 can receive an input signal from I/O through via 3812-2 and/or receive an output signal. Such an input signal can be received at and/or such an output signal can be provided at a terminal at first side 3802. In some embodiments, a first back side circuit 3870-0 can be a three terminal ESD circuit.

According to embodiments, power supply voltages and/or other signals can be received and/or provided at terminals of an IC device. Such signals can be routed through a substrate by combinations of buried conductive lines and through vias. Such terminals can take any form suitable to the IC device fabrication process, expected package, or other constraint.

FIG. 39A is a side cross sectional view showing an IC device connection according to an embodiment. FIG. 39A shows a through via 3912 formed within a substrate 3902 that can make contact with a back side routing portion 3924-0 substantially at a back surface 3928. A terminal 3908-0 can be formed over (with respect to back surface 3928) and have a conductive connection with through via 3912 through back side routing 3924-0. In the embodiment shown, an inter-device connection (e.g., ball or micro-ball) 3992 can enable a conductive connection between terminal 3908-0 and another device and/or structure.

FIG. 39B is a side cross sectional view showing an IC device connection according to another embodiment. FIG. 39B shows items like those of FIG. 39A, and such like items are referred to by the same reference characters. FIG. 39B can differ from that of FIG. 39A in that a terminal 3908-1 can be offset from a through via 3912 (e.g., not formed over through via 3912), but conductively connected thereto by back side routing portion 3924-1.

FIG. 39C is a side cross sectional view showing an IC device connection according to another embodiment. FIG. 39C shows items like those of FIG. 39B, and such like items are referred to by the same reference characters. FIG. 39C can differ from that of FIG. 39B in that a terminal 3908-1 can be connected to through via 3912 by a back side circuit 3970. Back side routing portion 3924-1 can connect through via 3912 to back side circuit 3970, and back side routing portion 3924-2 can connect terminal 3908-1 to back side circuit 3970.

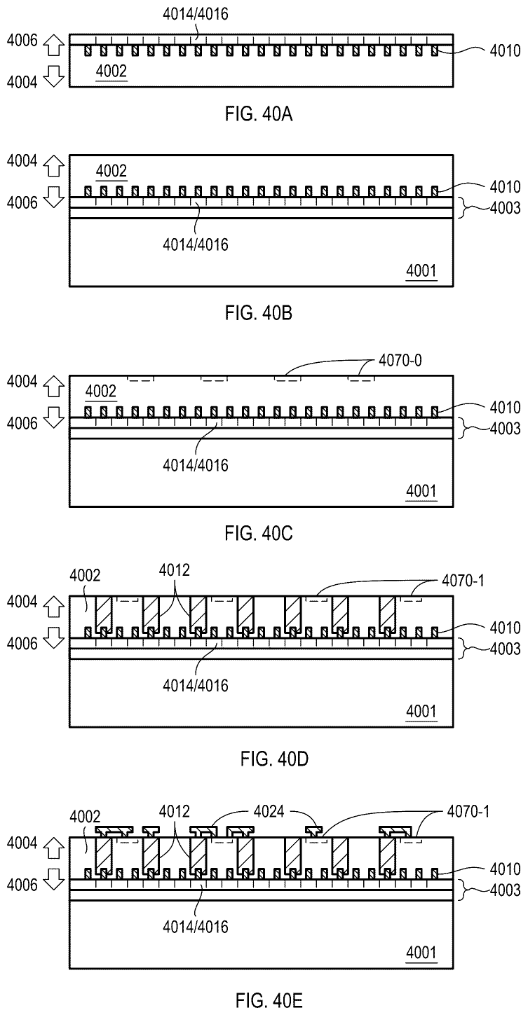

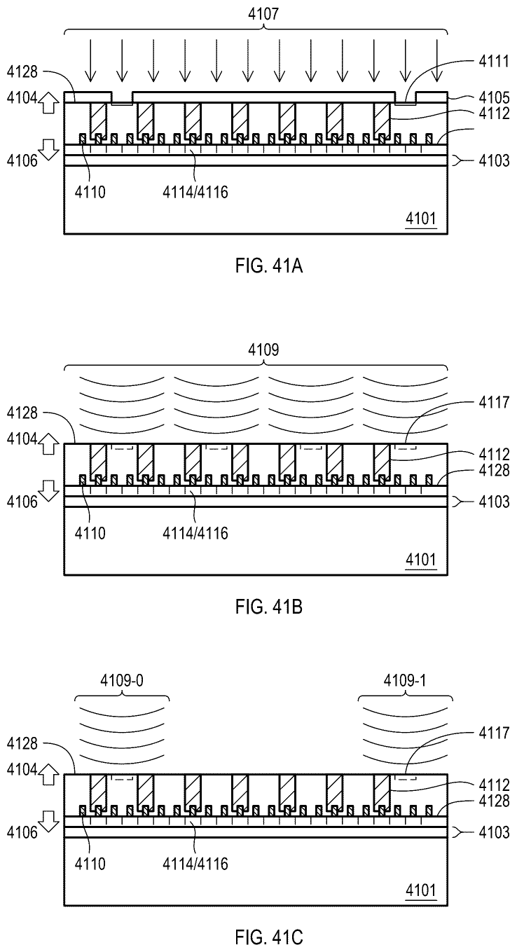

According to embodiments, IC devices can be fabricated with circuits on front and back sides of a substrate, where such circuits can be conductively connected with through vias formed in the substrate. Such structures can be fabricated using any suitable processes. FIGS. 40A to 41C show fabrication steps according to embodiments. However, such fabrication steps should not be construed as limiting.

FIGS. 40A to 40E are a sequence of side cross sectional views showing the fabrication of an IC device according to an embodiment. FIG. 40A shows a substrate 4002. Buried conductive lines 4010 and rows of IGFETs 4014/4016 can be formed at a second side 4006 of substrate 4002. Rows of IGFETs 4014/4016 can take the form of any of those described herein, or equivalents. Selected IGFETs of rows 4014/4016 can be formed with conductive connections to buried conductive lines 4010.

FIG. 40B shows a second side 4006 of substrate 4002 being bonded to a bonding substrate 4001 at bonding interface 4003. Such an action can enable a first side 4004 of substrate 4002 to be further processed.

FIG. 40C shows the formation of all or portions of back-side circuits 4070-0 before the formation of through vias. However, as noted below, all or a portion of back-side circuits can be formed at a later point in the process.

FIG. 40D shows the formation of through vias 4012 within substrate 4002 and in contact with buried conductive lines 4010. FIG. 40D also shows how all or portions of back-side circuits 4070-1 can be formed during or after the formation of through vias 4012.

FIG. 40E shows the formation of back side routing 4024 at a first side 4004. A back side routing 4024 can provide conductive paths to through vias 4012, including from a through via 4012 to a back side circuit 4070-1.

According to embodiments, the formation of back side circuits on a substrate can occur after the formation of front side circuits. To reduce adverse effects of heat cycles on front side circuits, localized heat processing steps can be applied to a back side in the formation of back side circuits.

FIG. 41A to 41C are a sequence of side cross sectional views showing the fabrication of back side circuits of an IC device according to an embodiment. FIGS. 41A to 41C include items like those of FIG. 40D, and such like items are referred to by the same reference but with the leading digits being “41” instead of “40”. FIG. 41A shows the formation of a mask 4105 on a back surface 4128 of substrate 4102. dopants 4107 can be introduced through openings of mask 4105 to create initial doped regions 4111 in substrate 4102. In some embodiments, multiple masks and different dopants can be used to form various different doped regions in a substrate.

FIG. 41B shows a heat treatment 4109 that can be applied to diffuse dopants to create doped regions 4117 with a desired dopant profile. Heat treatment 4109 can be localized to a back side 4104. Such a heat treatment can take any suitable form, including but not limited to a laser anneal.

FIG. 41C shows a heat treatment 4109-0/1 that can be applied to diffuse dopants to create doped regions 4117 with a desired dopant profile. Heat treatments 4109-0/1 can occur in place of, or in addition to, those shown in FIG. 41B. Heat treatments 4109-0/1 can be localized to a back side 4104 and also localized to particular areas of a back surface 4128. Such a heat treatment can take any suitable form, including but not limited to a raster laser anneal.

While embodiments can include IC devices and methods, embodiments can also include systems in having an IC device in combination with one or more other IC devices and/or packaging structures.

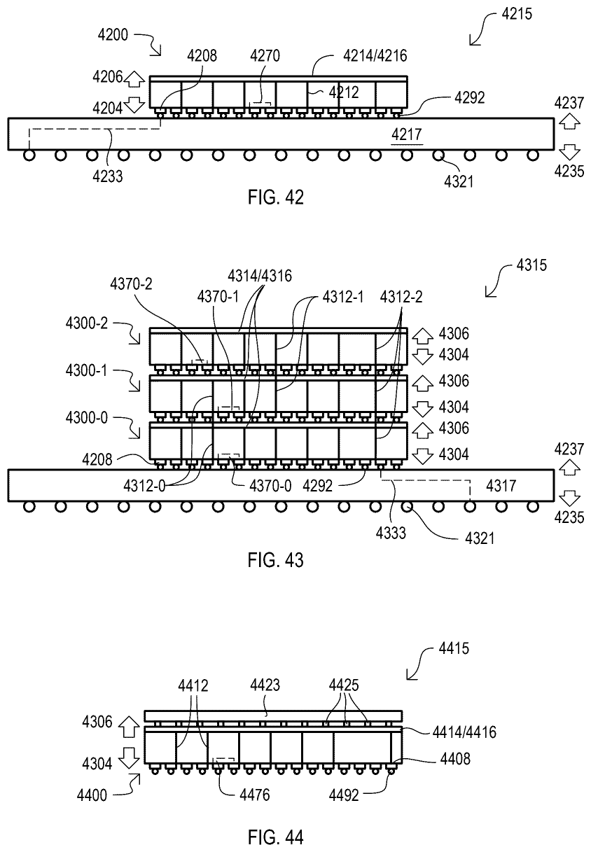

FIG. 42 is a side cross sectional view of a system 4215 according to an embodiment. A system 4215 can include an IC device 4200 and a redistribution layer (RDL) structure 4217. An IC device 4200 can include rows of IGFETs 4214/4216 formed at a second side 4206, through vias 4212, and terminals 4208, which can take the form of any of those described herein or equivalents. In the embodiment shown, IC device 4700 can include a back side circuit 4270 formed at first side 4204. An RDL structure 4217 can have a first side 4235 and a second side 4237, and can provide signal paths (one shown as 4233) from a smaller area of a second side 4237 to second terminals 4321 formed over a larger area of a first side 4235.

Referring still to FIG. 42, an IC device 4200 can have a first side 4204 facing a second side 4237 of an RDL structure 4117. Terminals 4208 of IC device 4200 can be conductively connected to a second side 4237 of RDL structure 4217 by inter-device connections 4292, which can have conductive connections to signals paths 4233 of RDL structure 4217.

FIG. 43 is a side cross sectional view of a system 4315 according to another embodiment. A system 4315 can include items like those of FIG. 42, and such like items are referred to by the same reference character but with the leading digits being “43” instead of “42”. A system 4315 can differ from that of FIG. 42 in that a second IC device 4300-1 can be stacked onto a first IC device 4300-0, which is connected to an RDL structure 4317. Further, a third IC device 4300-2 can be stacked onto second IC device 4300-1. A first side 4304 of second IC device 4300-1 can face a second side 4306 of first IC device 4300-0. A first side 4304 of third IC device 4300-2 can face a second side 4306 of second IC device 4300-2.

Referring still to FIG. 43, while each IC device 4300-0 to -2 can include one or more corresponding back side circuits (4370-0 to -2), in some embodiments, fewer devices can include back side circuits, including only one. FIG. 43 also shows how conductive vias can provide conductive paths through multiple IC devices, including through first and second IC devices 4312-0, second and third IC devices 4312-1, and all three IC devices 4312-2. Such conductive paths can include any of the signal/voltages as described herein, or equivalents.

While embodiments can include IC devices having IGFET circuits on one side of a substrate that receive multiple power supplies from the other side of the substrate, alternate embodiments can include IGFET circuits that receive one power supply from an opposing side of a substrate, and another power supply from the same side of a substrate.

FIG. 44 shows a system 4415 according to another embodiment. A system 4415 can include an IC device 4400 and top side distribution structure 4423. An IC device 4400 can include items like IC device 4200 of FIG. 42, and like items are referred to by the same reference character but with the leading digits being “44” instead of “42”. IC device 4400 can receive a first power supply voltage at a terminals 4408, and provide such a power supply voltage to IGFET rows 4414/4416 by way of through vias 4412. In some embodiments, such a first power supply voltages can be provided to select IGFETs in rows of IGFETs having a first conductivity type.

A top distribution structure 4423 can receive a second power supply voltage, and provide such a voltage to IGFET rows 4414/4416 with top connections 4425. A top distribution structure 4423 can be rigid member with conductive connections, as described for an RDL structure. A top distribution structure 4423 can receive a second power supply voltage through any suitable connection to a package that contains a system 4415.

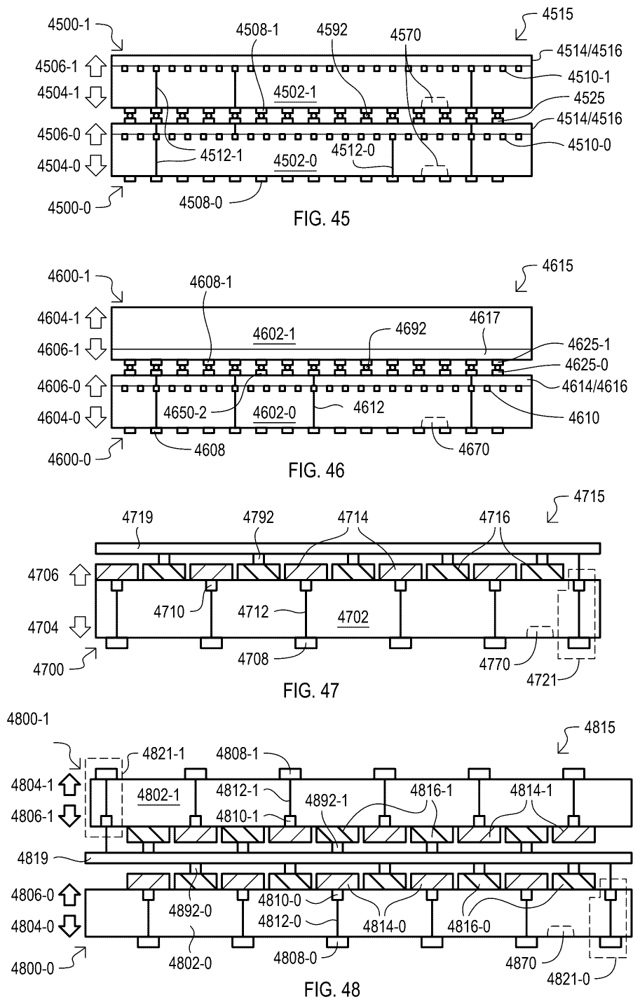

FIG. 45 is a side cross sectional view of a system 4515 according to another embodiment. A system 4515 can include a first IC device 4500-0 and a second IC device 4500-1 stacked on top of one another. A first and second IC devices 4500-0/1 can both include a substrate 4502-0/1, first (e.g., back) sides 4504-0/1 and a second (e.g., front) sides 4506-0/1, buried conductive lines 4510-0/1, through vias 4512-0/1, and terminals 4508-0/1.

A second side 4506-0 of first IC device 4500-0 can face a first side 4504-1 of second IC device 4500-1. First IC device 4500-0 can include top connections 4525 that can be conductively connected to terminals 4508-1 of second IC device 4500-1 with inter-device connections 4592. Either or both of IC devices 4500-0/1 can include a back side circuit 4570. Through vias 4512-0 can connect a terminal 4508-0 to a buried conductive line 4510-0. In some embodiments, through vias 4512-1 can extend through both devices with inter-device connections.

FIG. 46 is a side cross sectional view of a system 4615 according to another embodiment. A system 4615 can include items like those of FIG. 45, and like items are referred to by the same reference character but with the leading digits being “46” instead of “45”. System 4615 can differ from that of FIG. 45 in that a second side 4606-0 of first IC device 4600-0 can face a second side 4606-1 of second IC device 4600-1.

Referring still to FIG. 46, a second IC device 4600-1 can include circuits 4617 formed at a second surface 4606-1. In some embodiments, such circuits 4617 can receive power supply voltages through top connectors 4650-2. Top connectors 4650-2 can receive such power supply voltages from a supply path through first IC device 4600-0 that can include a terminal 4608, a through via 4612, top connector 4625-0 and inter-device connection 4692.

FIG. 47 is a side cross sectional of a system 4715 according to a further embodiment. A system 4715 can include an IC device 4700 and top side distribution structure 4719. An IC device 4700 can include a substrate 4702 with a first and second sides 4704/4706. First and second rows of IGFETs 4714/4716 can be formed at a second side 4706. First rows of IGFETs 4714 can include IGFETs of a first conductivity type, selected of which can receive a first power supply voltage from a supply path that includes a terminal 4708, through via 4712, and buried conductive line 4710. Second rows of IGFETs 4716 can include IGFETs of a second conductivity type, selected of which can receive a second power supply voltage from a supply path that includes a power distribution layer 4719 and inter-device connections 4792. In some embodiments, an IC device 4700 can include a back side circuit 4770.

A power distribution layer 4719 can be an interconnect layer formed over first and second IGFET rows 4714/4716. Alternatively, a power distribution layer 4719 can be a separate device, like an RDL structure or the like. While FIG. 47 shows power distribution layer 4719 receiving a second power supply through a power supply path 4721 that extends through first IC device 4700, in alternate embodiments, power distribution layer 4719 can receive a second power supply from a power supply path independent of first IC device 4700.

FIG. 48 is a side cross sectional of a system 4815 according to another embodiment. A system 4815 can include items like those of FIG. 47, and such like items are referred to by the same reference characters but with the leading digits being “48” instead of “47. System 4815 can differ from that of FIG. 47 in that it includes a second IC device 4800-1 connected to power distribution layer 4819 in the same manner as a first IC device 4800-0. As in the case of FIG. 47, while power supply distribution layer 4819 can receive a second power supply voltage through a power supply path 4821-1 that extends through as second IC device 4800-1, alternate embodiments can include a power supply distribution layer 4819 that receives a second power supply independent of first or second IC devices 4800-0/1.

In some embodiment, a supply distribution layer 4719/4819 can also include portions operating as a heat sink. In some embodiments, such a heat sink can have thermally conductive contacts with dummy vias in a corresponding IC device (4700, 4800-0/1).

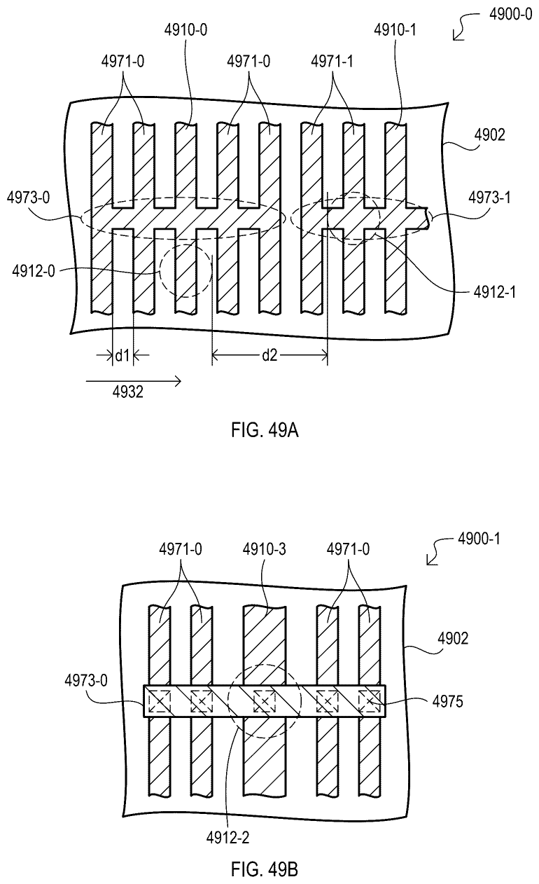

FIG. 49A is a top plan view of an IC device 4900-0 according to another embodiments. An IC device 4900-0 can include source conductive lines 4910-0/1 and distribution conductive lines 4971-0/1. Source conductive lines 4910-0/1 can be formed in a surface of a substrate 4902 as described for embodiments herein and equivalents. Distribution conductive lines 4971-0/1 can be formed in any suitable manner, including in a surface of substrate 4902, on a surface of substrate 4902, or combinations thereof. In the embodiment of FIG. 49A, distribution conductive lines 4971-0/1 can be formed in a substrate, and with the same process used to form source conductive lines 4910-0/1.

Source conductive lines 4910-0/1 can receive a power supply from through vias 49112-0/1. Such a power supply can then be provided to distribution conductive lines 4971-0/1 with conductive structures 4973-0/1. While FIG. 49A shows an arrangement with one source conductive line providing a power supply to four distribution conductive lines, alternate embodiments can include source lines providing power to fewer or a greater number of distribution conductive lines.

Referring still to FIG. 49A, a spacing between through vias 4912-0/1 in a second direction 4932 (d1) can be greater than a spacing between adjacent distribution conductive lines 4971-0/1 (d2) or a spacing between and source conductive line and an adjacent distribution conductive line.

FIG. 49B is a top plan view of an IC device 4900-1 according to a further embodiment. FIG. 49B shows a source conductive line 4910-3 that can provide power to distribution conductive lines 4971-0. A source conductive line 4910-3 can receive power from a through via 4912-2. Source conductive line 4910-3 can provide power to distribution conductive lines 4971-0 with a conductive structure 4973-0 that can be formed above source and distribution conductive lines (4910-3, 4971-0). In the embodiment shown, conductive structure 4973-0 can have a conductive connection to source and distribution conductive lines (4910-3, 4971-0) with contacts (one shown as 4975).

Although embodiments above may show ball type electrical connections between IC devices, it is understood that the connections may be direct “pad to pad” type electrical connections. Such connections may include thermal compression bonding by applying thermal and mechanical pressure in the bonding process. In this case, the connections may be formed in an insulator layer surface of each IC device including enough empty space for the metals to expand during the heating process and form a bond between adjoining IC devices through diffusion of the respective metals.

It is also understood that the pattern and etch steps described above in the embodiments may use extreme ultraviolet (EUV) patterning. In such a case, EUV light may be reflected off (as in a mirror) a reticle (photomask) imprinted with a pattern and focused onto the IC device to form the desired lithographic pattern as opposed to using a reticle in which the light is transmitted through a reticle. In this way, the light may have less distortion, scattering, and/or absorption and finer features may be formed.

It should be appreciated that reference throughout this specification to “one embodiment” or “an embodiment” means that a particular feature, structure or characteristic described in connection with the embodiment is included in at least one embodiment of the present invention. Therefore, it is emphasized and should be appreciated that two or more references to “an embodiment” or “one embodiment” or “an alternative embodiment” in various portions of this specification are not necessarily all referring to the same embodiment. Furthermore, the particular features, structures or characteristics may be combined as suitable in one or more embodiments of the invention.

Similarly, it should be appreciated that in the foregoing description of exemplary embodiments of the invention, various features of the invention are sometimes grouped together in a single embodiment, figure, or description thereof for the purpose of streamlining the disclosure aiding in the understanding of one or more of the various inventive aspects. This method of disclosure, however, is not to be interpreted as reflecting an intention that the claims require more features than are expressly recited in each claim. Rather, inventive aspects lie in less than all features of a single foregoing disclosed embodiment. Thus, the claims following the detailed description are hereby expressly incorporated into this detailed description, with each claim standing on its own as a separate embodiment of this invention.

While this invention has been described with reference to illustrative embodiments, this description is not intended to be construed in a limiting sense. Various modifications and combinations of the illustrative embodiments, as well as other embodiments of the invention, will be apparent to persons skilled in the art upon reference to the description. It is therefore intended that the appended claims encompass any such modifications or embodiments.

1. A method, comprising:
receiving a first power supply voltage at a first terminal;
receiving a second power supply voltage at a second terminal;
receiving a third power supply voltage at a third terminal, the first, second and third terminals substantially at a first side of an IC device;
providing a first row first insulated gate field effect transistors (IGFETs), a second row of IGFETs, and third IGFETs substantially at a second side of the IC device, the first side opposite the second side, each IGFET including a first source/drain (S/D) and a second S/D,
a plurality channels disposed between the first and second S/D of the respective IGFET, and
a control gate that substantially surrounds the plurality of channels of the respective IGFET, the plurality of channels providing a controllable impedance path between a first and second S/D of the respective IGFET;
coupling the first power supply voltage from the first terminal to a first conductive line with a first conductive via;
coupling the second power supply voltage from the second terminal to a second conductive line with a second conductive via;
coupling the third power supply voltage from the third terminal to a third
conductive line with a third conductive via, the first, second, and third
conductive vias disposed between the first and second sides;
coupling the first power supply voltage from the first conductive via to a first conductive line;
coupling the second power supply voltage from the second conductive via to a second conductive line;
coupling the third power supply voltage from the third conductive via to a third conductive line, the first, second and third conductive lines being buried in and proximate to the second side;
coupling the first power supply voltage from the first conductive line to at least one first S/D of an IGFET of the first row;
coupling the second power supply voltage from the second conductive line to at least one first S/D of an IGFET of the second row; and
coupling the third power supply voltage from the third conductive line to at least one first S/D of a third IGFET; wherein
the first power supply voltage is separate from the third power supply voltage.

2. The method of claim 1, wherein:
the first power supply voltage is substantially the same as the third power supply voltage.

3. The method of claim 1, wherein:
the third power supply voltage has a greater magnitude than the first power supply voltage.

4. The method of claim 1, further including:
the IGFETs of the first row are of a first conductivity type;
the IGFETs of the second row are of a second conductivity type;
the third IGFETs are of the second conductivity type;
providing fourth IGFETs of the first conductivity type;
forming logic circuits with at least a first portion of the first row and at least a second portion of the second row;
forming a second circuit with the third and fourth IGFETs;
coupling the first power supply voltage to a first S/D of an IGFET in the first portion and a first S/D of a fourth IGFET; and
coupling the second power supply voltage to a first S/D of an IGFET in the second portion and to a first S/D of a third IGFET.

5. The method of claim 4, further including:
forming the third IGFETs with channel widths that are greater than channel widths of the IGFETs of the first row; and
forming the fourth IGFETs with channel widths that are greater than channel widths of the IGFETs of the second row.

6. The method of claim 1, further including:
forming the first conductive via to have a first cross sectional area in plane parallel to the second side; and
forming the third conductive via to have a third cross sectional area in plane parallel to the second side that is greater than the first cross sectional area.

7. The IC device of claim 1, further including:
providing a first electrostatic discharge (ESD) protection circuit formed at the first side that is electrically connected to at least the first terminal; and
providing a second ESD protection circuit formed at the first side that is electrically connected to at least the third terminal.

8. The method of claim 1, further including:
forming a backside routing network at the second side that includes a first routing portion configured to electrically connect the first terminal to the first via;
a second routing portion configured to electrically connect the second terminal to the second via; and
a third routing portion configured to electrically connect the third terminal to the third via.

9. The method of claim 8, wherein:
the third routing portion comprises conductive lines having a width greater than those of the first routing portion.

10. The method of claim 1, further including:
generating an output signal with a circuit that includes at least the third IGFETs;
coupling the output signal from the circuit to an output conductive structure buried in and proximate the second side below the at least the third IGFETs;
coupling the output signal from the output conductive structure to the first side with an output via disposed between the second side and the first side; and
coupling the output signal from the output via to an output terminal substantially at the first side.

11. The method of claim 10, wherein:
the output via has a larger cross sectional area than that of the first, second and third conductive vias in a plane parallel to the first side.

12. The method of claim 1, further including:
the third conductive line is disposed in a first direction;
providing a fourth conductive line is disposed in the first direction aligned with the third conductive line;
forming a circuit with at least one IGFET from the first row that includes an input;
providing an input conductive structure disposed between the third and fourth conductive lines, the input conductive structure electrically connected to the input of the circuit; and
providing a signal path between the input conductive structure and an input terminal at the first side with an input conductive via.

13. The method of claim 12, wherein:
the third and fourth conductive lines have a first width in a second direction substantially perpendicular to the first direction; and
the input conductive structure has a second width in the second direction that is greater than the first width.

14. The method of claim 1, further including:
the third conductive line is disposed in a first direction;
providing a fourth conductive line is disposed in the first direction aligned with the third conductive line;
forming a circuit with at least one IGFET from the first row that includes an output;
providing an output conductive structure disposed between the third and fourth conductive lines, the output conductive structure electrically connected to the output of the circuit; and
providing a signal path between the output conductive structure and an output terminal at the first side with an output conductive via.

15. The method of claim 14, wherein:
the third and fourth conductive lines have a first width in a second direction substantially perpendicular to the first direction; and
the output conductive structure has a second width in the second direction that is greater than the first width.

16. The method of claim 1, further including:
forming at least one circuit element substantially at the first side.

17. The method of claim 16, wherein:
the at least one circuit element is selected from the group of: a capacitor, an inductor, and a resistor.

18. The method of claim 16, wherein:
the at least one circuit element comprises a power gating circuit configured to selectively electrically connect the first terminal to the first conductive via.

19. The method of claim 16, wherein:
the at least one circuit element comprises an output driver circuit.

20. The method of claim 1, further including:
forming resistive conductive via between the first and second side, the resistive conductive via having a greater resistance than the first, second and third conductive vias.
